(19) United States
(12) Patent Application Publication
(10) Pub. No.: US 2026/0287374 A1
(43) Pub. Date: Sep. 24, 2026

(54) PREDICTIVE POWER AND THERMAL MANAGEMENT OF A VEHICLE ECU

(71) Applicant: Hitachi Astemo Americas, Inc., Harrodsburg, KY (US)

(72) Inventor: Subrata Kumar KUNDU, Canton, MI (US)

(21) Appl. No.: 19/084,126

(22) Filed: Mar. 19, 2025

(51) Int. Cl. G01C 21/34; B60W 60/00; H05K 7/20

(52) U.S. Cl. CPC G01C 21/3469; B60W 60/0015; G01C 21/3461; H05K 7/20863; H05K 7/20872

(57) ABSTRACT

Examples include a system that determines a plurality of candidate routes between a source location for a vehicle and a destination location, and determines, for each candidate route, a predicted thermal load on a vehicle electronic control unit (ECU) of the vehicle for traversing the candidate route. The system determines a cooling technique for the vehicle ECU based on the predicted thermal load for each candidate route, and selects a first route of the candidate routes based at least on the first route predicted to have a lower energy expenditure for cooling the vehicle ECU than at least one other route. The system sends, to the vehicle, information related to the first route and at least one selected cooling technique determined for the first route to enable the vehicle to utilize the selected cooling technique for cooling the vehicle ECU during traversal of the first route.

### BACKGROUND

Advanced driver assistance systems (ADAS) and autonomous driving (AD) systems are systems that automate or otherwise enhance vehicle control for improved safety, automated navigation, automated driving, improved convenience, improved efficiency, and the like. These AD/ADAS vehicles are gaining wide acceptance with recent rapid advancements in sensing, data processing, artificial intelligence (AI), and connectivity technologies, and are expected to play a major role in the future of mobility. Such AD/ADAS vehicles may employ one or more system-on-chip (SoC) processors or other high-power processors as AD/ADAS electronic control units (ECUs). For instance, AD/ADAS ECUs may be used for processing large amounts of sensor data in real time for performing automated and semi-automated driving. These real-time data processing demands result in the consumption of large amounts of power by the ECUs, which, in turn, requires effective thermal management of the ECUs.

### SUMMARY

In some implementations, a system may determine a plurality of candidate routes between a source location for a vehicle and a destination location, and may determine, for each candidate route, a predicted thermal load on a vehicle electronic control unit (ECU) of the vehicle for traversing the candidate route. The system determines a cooling technique for the vehicle ECU based on the predicted thermal load for each candidate route, and selects a first route of the candidate routes based at least on the first route predicted to have a lower energy expenditure for cooling the vehicle ECU than at least one other route. The system sends, to the vehicle, information related to the first route and at least one selected cooling technique determined for the first route to enable the vehicle to utilize the selected cooling technique for cooling the vehicle ECU during traversal of the first route.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features.

FIG. 1 illustrates an example system for power and thermal management of a vehicle ECU according to some implementations.

FIG. 2 is a flow diagram illustrating an example process for determining thermal management techniques to employ for a vehicle ECU during a trip according to some implementations.

FIG. 3 is a flow diagram that illustrates a continuation of the process of FIG. 2 according to some implementations.

FIG. 4 is a combined flow diagram and block diagram illustrating an example architecture and process for determining a route for a vehicle that takes thermal management of a vehicle ECU into consideration according to some implementations.

FIG. 5 is a flow diagram illustrating an example process executed by the data analytics platform 145 according to some implementations.

FIG. 6 is a flow diagram that illustrates a continuation of the process of FIG. 5 according to some implementations.

FIG. 7 illustrates an example of determining candidate routes between a source location and a destination location according to some implementations.

FIGS. 8A and 8B illustrate examples of intersections according to some implementations.

FIG. 9 is a flow diagram illustrating an example process for determining POZs for various different criteria according to some implementations.

FIG. 10 illustrates an example of determining a POZ in which a current road segment falls outside of an intersection functional area according to some implementations.

FIG. 11 illustrates an example of determining a POZ according to some implementations.

FIGS. 12A and 12B illustrate examples of vehicle sensor operation at a POZ according to some implementations.

FIG. 13 illustrates an example configuration of a virtual model of a system-on-chip (SoC) according to some implementations.

FIG. 14 is a flow diagram illustrating an example process for determining a tiling configuration to employ for a virtual AI model according to some implementations.

FIG. 15 is a flow diagram illustrating an example process for determining thermal management techniques to employ for a vehicle ECU during a trip according to some implementations.

FIG. 16 illustrates an example schematic diagram of an autonomous driving control architecture according to some implementations.

### DESCRIPTION

Some implementations herein are directed to techniques and arrangements for proactive thermal management and power management of high-performance processors employed in vehicles, such as vehicle ECUs that include a system on chip (SoC), or similar ECUs that may be used for automated and semi-automated driving systems. For example a high-performance vehicle ECU may include a high-performance SoC. Proper thermal management of a vehicle ECU according to the implementations herein can help ensure the reliability of the vehicle ECU by preventing degraded performance and/or damage to the vehicle ECU, and thereby improving reliability of the vehicle, such as when performing autonomous driving.

Examples herein may predict the power consumption of a high-performance vehicle ECU and may further predict the thermal management to be performed for the vehicle ECU in view of the predicted power consumption. Conventional systems are not able to accurately predict ECU usage for a trip to be traversed by a vehicle. On the other hand, implementations herein may predict in advance the vehicle ECU computational load for every road segment of a route for an upcoming trip, and may perform thermal management of the vehicle ECU during the trip by taking into consideration the predicted power consumption of the vehicle ECU for each road segment and the corresponding thermal load on the vehicle ECU. In some examples, a “thermal load” may include the amount of heat energy that is to be removed to maintain a desired temperature range within the vehicle ECU.

Further, some examples include techniques to predict the power consumption and thermal management of a vehicle ECU having a SoC by estimating the utilization of the vehicle ECU for the entire route using a virtual model of the SoC and by performing an analysis based on Precautionary Observation Zones (POZs), which are areas of road segments for which predicted sensor usage may be determined. Efficiency and reliability of a vehicle ECU able to perform automated driving can be significantly increased if prediction of computing capacity usage, prediction of power consumption, and corresponding thermal management can be performed effectively. Examples herein proactively determine and account for anticipated power consumption and corresponding thermal management of at least one vehicle ECU, and provide significant benefits to ensure the reliability, efficiency, and performance of the vehicle ECU.

Some examples herein predict the SoC usage of the vehicle ECU for some or all of the road segments of a candidate or selected route. The concept of a POZ may be employed to estimate a sensor Field of View (FOV) for each road segment of a particular route. Corresponding deep neural networks or other machine-trained models, as well as virtual SoC models may be used to estimate the load on the SoC of a vehicle ECU at each road segment of a particular route. Based on the estimated processing requirements at each road segment, suitable thermal management techniques may be designated for various different road segments. In some cases, the determination of the thermal load on the vehicle ECU may be based on determining POZs for each road segment along the route. For example the POZs may be determined using the techniques described below, as well as in, e.g., U.S. Pat. No. 12,123,729, which is incorporated by reference herein.

The examples herein may also determine how to efficiently utilize other available computing resources to perform the necessary processing tasks, such as by using vehicular edge controllers (VECs) where available, and through communication with a central data management platform. The examples herein may determine POZs as regions of interest at locations along the route, and where particular ones of the vehicle cameras or other sensors should monitor. The examples herein may also prioritize or otherwise rank obstacles or road features that should be recognized with higher accuracy, and may determine a corresponding resource allocation strategy.

There are different kinds of sensing techniques or sensors used for AD and/or ADAS applications. Commonly used sensors include mono cameras, stereo cameras, infrared cameras, radar, lidar, laser, ultrasonic sensors, satellite positioning system, compass, inertial measurement unit (IMU), etc. For any specific driver-assistance system application or any specific level of automated driving, sensors may be selected considering their advantages and disadvantages including range of motion, type of detection ability, power requirement, cost, amount of data generated, etc. Generally, level-1 and/or level-2 automated vehicle functions (like adaptive cruise control-ACC) could be realized using a standalone sensor like mono or stereo camera, or a combination of a camera and radar. Multiple sensors are mostly required to realize a higher level of automated driving like level-3 to level-5. For a fully automated vehicle, such as level-4 and level-5, it is essential to continually monitor 360 degrees around the vehicle to avoid any obstacles and navigate safely, which requires multiple sensors to work together. Each sensor has its own advantages and disadvantages. For instance, it would be difficult to use a single sensor that would be able to meet all weather requirements considering recognition accuracy and range. Thus, automotive manufacturers use sensor fusion systems based on the level of autonomous driving of the vehicle, as well as the cost of the overall system.

In some examples, the system herein may offload computational tasks to one or more vehicular edge computing devices (VECs) that are located near the vehicle's route and that are able to communicate with nearby vehicles through one or more roadside units (RSUs). For instance, in contrast to communications with computing devices at data centers or other cloud infrastructure locations, the VECs herein may be better positioned to execute time-critical computational tasks due to the closer location of these processing units to the roadside, as compared to the often relatively remote location of cloud-based servers. For example, VECs may avoid or substantially reduce the network latency of data communications between the vehicle and off-vehicle ECUs. Furthermore, other vehicles with available sensing and computational resources that are near a VEC may provide the sensing and/or computational resources to the VEC to also process and/or provide data to the vehicle. For instance, in some examples, images from an infrastructure camera at a fixed location, or recognition results therefrom, may be provided by the VEC to the vehicle for aiding the vehicle in navigating the corresponding location.

Examples herein may provide a combination of VECs, other vehicles with excess computational capacity, and more remotely located cloud-based service computing devices, which separately and/or together may provide sensing and computation resources to vehicles in need of additional computational resources. Accordingly, the examples herein may determine in advance where to request that a nearby VEC provide support with computational tasks for a vehicle that is not able to fully perform the necessary computations for traversing one or more road segments. For example, the remotely located service computing devices may assign the computational task to a nearby VEC according to the available computation resources on the VEC. Implementations herein may further identify certain regions along the route in advance as POZs, which are locations that may require higher levels of computational resources to realize autonomous driving. The system may perform scheduling for assigning and executing the offloaded computational tasks accordingly by scheduling available computation resources of the VECs and/or the cloud-based service computing devices.

To ensure vehicle safety, some examples herein may try to maximize the amount of automated driving time. For example, safe driving is not only important for individuals but also for any type of transportation or service business. Safety is one of the underlying reasons for wider development and rapid progress of automated driving systems. Fully or partially automated vehicles are equipped with multiple sensors to continuously monitor the vehicle surroundings to recognize obstacles for improving safety. Studies show that most road accidents are caused due to human driver errors. Thus, state of the art automated vehicles equipped with advanced sensing and data processing units may enable the use of improved algorithms to significantly reduce the incidence of vehicle collisions.

The cameras and other sensors of the vehicles herein may play a major role in detecting obstacles around the vehicles and road features to ultimately help avoid collisions. The vehicle ECUs herein may process the camera images and other sensor data in real time to determine one or more control signals for controlling the vehicle, and may send the control signals to various vehicle systems and/or actuators to control the vehicle. By deploying multiple redundant cameras and other high-resolution sensors around the vehicle in conjunction with use of one or more vehicle ECUs having SoCs with high processing capacity, a vehicle may be able to operate autonomously in all conditions.

In some examples herein, before beginning a trip, the vehicle may share, with the service computing devices, its current location, destination, sensor configuration information, and specifications of the vehicle ECU with SoC. The service computing devices identify candidate routes to the destination and may calculate POZs for the candidate routes. As mentioned above, the POZ may be a region that the vehicle should monitor with its sensors to ensure safety of the vehicle. Further, based on the POZs for each road segment of each candidate route, the system may predict the computing load on the SoC of the vehicle ECU, may predict the power consumption of the ECU for each segment, and may determine a thermal load management strategy for each road segment, which may include taking into consideration predicted thermal loads for the other road segments in the candidate route. POZs may be determined for all the road segments and/or waypoints along the route. In some cases, a POZ may be a 3D region that varies depending e.g., the road type, waypoint locations, etc., as discussed additionally below. The service computing devices may select an optimal route for maximizing the amount of time for automated driving while ensuring that the thermal load on the vehicle ECU is managed to avoid damage or degraded performance of the SoC.

In some examples, based on the vehicle sensor configuration and vehicle ECU/SoC specifications, the service computing devices may identify the road segments along the route where the vehicle may require additional computational resources to avoid overheating of the vehicle ECU. The service computing devices may share the vehicle information with the VECs in the identified locations and the expected time at which the vehicle is expected to approach the road segment nearest to the respective VEC. Upon receiving the vehicle information from the service computing devices, the respective VEC may analyze the scheduled computing tasks for that time segment, and based on the computing resource availability of the respective VEC, may confirm or reject the request to support the particular vehicle. Additionally, based on the feedback from the respective VECs, the service computing devices may update the routing information and may send the routing information to the vehicle. For instance, if a VEC is not able to support the request for the particular vehicle, the service computing devices may determine whether an alternative candidate route may be available for the vehicle.

In some examples, the vehicle may access a connected data analytics platform provided by the service computing devices and may provide information to the data analytics platform regarding the onboard sensors available on the vehicle, as well as providing the source location, the destination location, vehicle configuration information, vehicle ECU specifications, and so forth. Further, the vehicle may receive, from the data analytics platform, information about one or more optimal routes selected by the data analytics platform for reaching the destination location and a thermal management technique to use for the vehicle ECU along each segment of the route. Alternatively, in other examples, the route determination and thermal management techniques to use may be performed by a vehicle ECU onboard the vehicle, or by a VEC located proximate to the vehicle, along a route of the vehicle, or the like.

For discussion purposes, some example implementations are described in the environment of predicting a processing load on a vehicle ECU SoC at each road segment of a route the vehicle will traverse, and further determining a predicted thermal load on the vehicle ECU. The predicted thermal load can be used to determine an appropriate thermal management countermeasure to ensure that the vehicle ECU remains sufficiently cool to operate as expected. The processing load on the vehicle ECU may be predicted based on the determination of one or more POZs that the vehicle will traverse. However, implementations herein are not limited to the particular examples provided, and may be extended to other types of vehicles, other types of communications, other types of computing device configurations, other types of computing platforms and architectures, and so forth, as will be apparent to those of skill in the art in light of the disclosure herein.

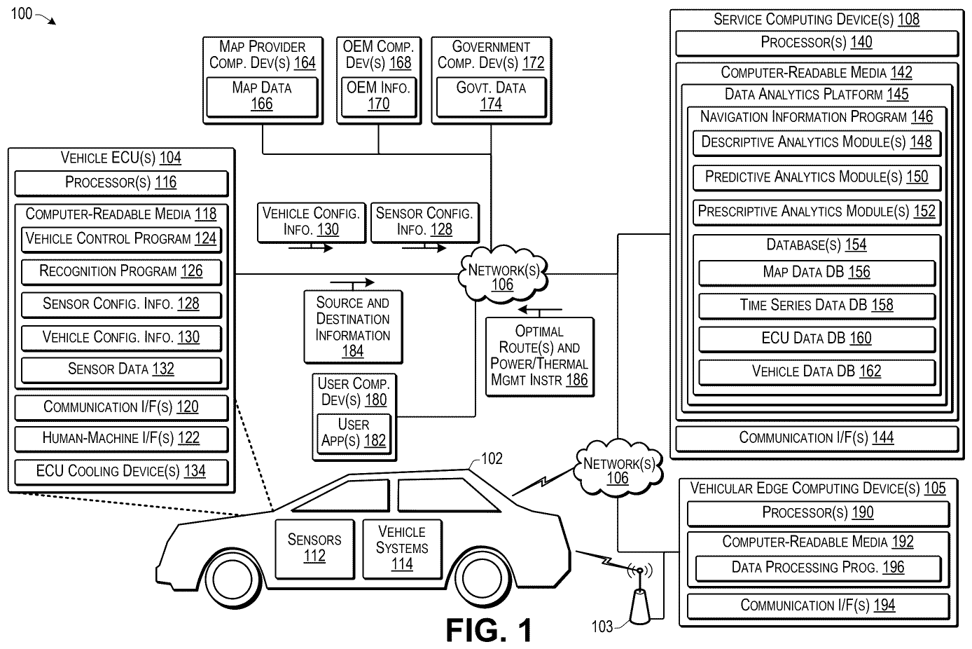

FIG. 1 illustrates an example system 100 for power and thermal management of a vehicle ECU according to some implementations. In this example, the system 100 includes a vehicle 102 having one or more vehicle electronic control units (ECUs) 104 able to communicate wirelessly with one or more roadside units (RSUs) 103 that are connected to one or more VECs 105. In addition, the vehicle ECUs 104 and the VECs 105 are able to communicate over one or more networks 106 with one or more service computing devices 108. The VECs 105 may also communicate with a plurality of other vehicles (not shown in FIG. 1), each of which may also include its own vehicle ECU(s). In some examples, the vehicle 102 and other vehicles discussed herein may be referred to as “connected vehicles” since they are connected for communication with one or more off-vehicle computing devices, such as the VECs 105 and/or the service computing devices 108. Further, while a single vehicle is illustrated for clarity in FIG. 1, there may be numerous vehicles 102 operating at the same time in the system 100 according to the examples herein.

The one or more networks 106 may include any appropriate network, including a wireless network, such as a cellular network; a wide area network, such as the Internet; a local area network, such an intranet; a local wireless network, such as Wi-Fi; close-range wireless communications, such as BLUETOOTH® or DSRC (dedicated short-range communications); a wired network, including fiber optics and Ethernet; any combination of the foregoing, or any other suitable communication network. Components used for such communication technologies can depend at least in part upon the type of network, the environment selected, or both. Protocols for communicating over such networks are well known and will not be discussed herein in detail.

Additionally, communication links between the RSUs 103 and the VECs 105 may include any of the one or more networks 106. For example, the VECs 105 and the RSUs 103 may communicate through wireless or wired communications. Further, the RSUs 103 may be configured to communicate wirelessly with the vehicle 102 such as through any type of wireless communications. Examples include 4G, 5G, or LTE cellular communications, other radio frequencies, Wi-Fi communications, V2X, other short range radio communications, or any other wireless communication technology.

In some examples, the vehicle ECUs 104 may include one or more ECUs or any of various other types of computing devices. For instance, the computing devices 104 may include one or more ADAS/AD ECUs or other types of ECUs having higher computational processing capabilities for processing sensor data and for controlling at least some of the vehicle systems, such as to perform ADAS and/or AD tasks, such as navigation, braking, steering, acceleration, deceleration, and so forth. In particular, to solve the challenge of processing a huge amount of sensor data in real-time, one or more System-on-Chips (SoCs) may be included in at least one of the vehicle ECUs 104 in examples herein. SoCs are typically powerful and complex to meet the real-time requirements of different applications including automated and semi-automated driving.

For example, studies show that both conventional rule-based algorithms and trained models, such as deep neural networks (DNNs) may be used to process the sensor data in a vehicle ECU 104. However, recent advances in artificial intelligence (AI) and advanced computing processing units has made the adoption of DNN-based algorithms for vehicle ECU data processing purposes in the automotive industry more advantageous. For instance, DNNs are widely adopted in automated industries due to their accuracy when considering different driving conditions. Different versions of DNNs having distinct architectures may be used in some examples herein for performing automated driving applications. For instance, multiple DNNs may be employed to perform separated functions of a vehicle ECU 104 including, e.g., perception, localization, prediction, path planning, control, etc. Alternatively, an end-to-end DNN model may be used to perform the entire operation on a vehicle ECU 104 having a SoC. Therefore, based on the level and type of automated vehicle control application, automotive OEMs and suppliers may design specific DNNs that can consider the sensor configurations and the vehicle output requirements.

Since DNNs are computationally expensive and automated vehicles sensors generate huge amounts of data that need to be processed in real-time, advanced System-on-Chip (SoC) are currently widely used for AD ECUs. SoCs are becoming very popular nowadays with their more powerful characteristics to meet the real time requirement of different applications of automated driving. A typical SoC included in a vehicle ECU 104 herein may include one or more processors, such as one or more central processing units (CPUs), input and output devices, interfaces for graphics and memories, storage, USB connectivity, and the like. Further, some examples of the SoCs used herein for vehicle ECUs 104 may also include a vision signal processing unit and one or more artificial intelligence (AI) accelerators, such as one or more neural processing units, deep learning accelerators, AI engines, and the like. In some cases, the SoCs herein may also include network-on-chip (NoC) technology, graphics processing units, digital signal processing units, and the like. The AI accelerator(s) used in the SoCs herein may generally include high-performance parallel computational modules that significantly assist in execution of the DNN or other machine-trained model within a shorter amount of time than would otherwise be the case if the AI accelerator were not used.

Since the SoC included in the vehicle ECU 104 herein may perform a huge amount of data processing in real-time, the SoC may generate a substantial amount of heat, which requires effective cooling and other thermal management techniques for ensuring reliable and efficient operation of vehicle ECU 104. Cooling techniques such as air cooling and/or liquid cooling may be employed in some examples herein for cooling a vehicle ECU 104 having a SoC. For instance, liquid cooling is generally more effective than air cooling for thermal management of an ECU SoC, as the liquid cooling typically provides a more effective and uniform heat dissipation than air cooling. Moreover, SoCs used for the vehicle ECUs 104 may have a high-power density which may rely on liquid cooling to ensure reliable and consistent operation of the vehicle ECU 104. Furthermore, in addition to at least one vehicle ECU 104 having a SoC, the vehicle ECUs 104 may also include one or more other ECUs, such as conventional lower-performance ECUs for controlling any of numerous other systems of the vehicles 102 respectively. For instance some vehicles 102 may have dozens or more of specialized ECUs as vehicle ECUs 104 for performing various functions throughout the vehicle 102.

In some cases, such as if it is predicted that the SoC of the vehicle ECU 104 may overheat, a portion of the computational tasks to enable the vehicle 102 to navigate certain road segments autonomously may be offloaded to a VECs 105 if there is a VEC 105 that is located proximate to the particular road segment. As several non-limiting examples, the VECs 105 may be near to a road segment, such as by being located within a mile, a half mile, a quarter mile, or less from one or more of the road segments traversed by the vehicle(s) 102, and to which the VECs 105 may provide information, recognition data, or other results of processing sensor data, such as from cameras and other sensors external to (i.e., not on board) the vehicle 102. For instance, in some cases, the VECs 105 may be located within several hundred yards of the RSUs 103 to which they are connected, and the RSUs 103 may be located within several dozen yards of the roads on which the vehicle 102 travels. Conversely, the service computing devices 108 may typically be located dozens, hundreds, or even thousands of miles from the RSUs 103, the vehicle 102, and the VECs 105. In some cases, the vehicle 102 may use information provided by the VEC 105 during navigation of the road segment. Thus, the VEC 105 may compensate for limited processing capability and/or limited sensor capabilities of the vehicle 102 by augmenting the information available to the vehicle 102 with sensor information and/or recognition information from infrastructure sensors and/or sensors of other vehicles. Additionally, in some examples, the service computing devices 108 may also provide computing resources to the vehicle 102, such as for computational tasks that are not time-critical. Further, as discussed below, the service computing devices 108 may provide numerous other functions for aiding the vehicle 102 in autonomous driving.

The vehicle 102 may further include onboard sensors 112 and one or more vehicle systems 114 that are in communication with the vehicle ECU(s) 104, such as via a CAN bus (controller area network bus) (not shown in FIG. 1) or any other suitable communication link. For example, the onboard sensors 112 may include a plurality of cameras and other types of sensors as discussed above. The sensors 112 play a major role in detecting obstacles around the vehicle 102 and road features that ultimately help the vehicle 102 to avoid collision. The vehicle ECU(s) 104 may process, in real time, the data received from the sensors 112 utilizing state-of-the-art algorithms, and based on the results of the sensor data processing, may send control signals to the vehicle systems 114 to control the vehicle 102. Providing multiple redundant high-resolution sensors 112 around the vehicle 102 with at least one high-power vehicle ECU including a SoC can enable the vehicle 102 to operate autonomously. However, the multiple sensors 112 may generate huge amounts of data that is processed by the vehicle ECU in real-time for realizing the automated driving.

In some examples, the amount of sensor data processing that needs to be performed may be controlled based on determining precautionary observation zones (POZs). For example, the service computing device 108 may determine one or more candidate routes for the vehicle 102 to traverse for a trip from a source location to a destination location, and may select the optimal route for the vehicle 102, based in part on predicted power and thermal management for the vehicle ECU 104. In other examples, the vehicle 102 or a VEC 105 may perform some determination of the POZs and selection of an optimal route, such as based on using data received from the service computing devices 108. In some cases, selection of the optimal route may include consideration of the data processing load and thermal load on the vehicle ECU in association with each respective POZ of each road segment of each candidate route, and in consideration of the ability to manage the thermal load on the vehicle ECU 104 during traversal of each candidate route.

Each vehicle ECU 104 may include one or more processors 116, one or more computer-readable media 118, one or more communication interfaces (I/Fs) 120, and one or more vehicle human-machine interfaces (I/Fs) 122. In some examples, the vehicle ECU(s) 104 may include one or more ADAS/AD ECUs including a SoC for controlling at least some of the vehicle systems 114, such as to perform ADAS and/or AD tasks, such as sensor data processing, navigation, braking, steering, acceleration, deceleration, and so forth. The vehicle ECU(s) 104 may also include one or more other ECUs, such as for controlling the sensors 112, the vehicle systems 114, and so forth.

“ECU” is a generic term for any embedded processing system that controls one or more of the systems, subsystems, or components in a vehicle. Software, such as a vehicle control program 124 and a recognition program 126 may be executed by one or more ECUs and may be stored in a portion of the computer-readable media 118 (e.g., program ROM, solid state storage, etc., as discussed below) associated with the respective ECU to enable the ECU to operate as an embedded system. ECUs on a vehicle may typically communicate with each other over a vehicle bus, such as the CAN bus mentioned above, according to a vehicle bus protocol. As an example, the CAN bus protocol is a vehicle bus protocol that allows ECUs and the vehicle systems 114 to communicate with each other without a host computer.

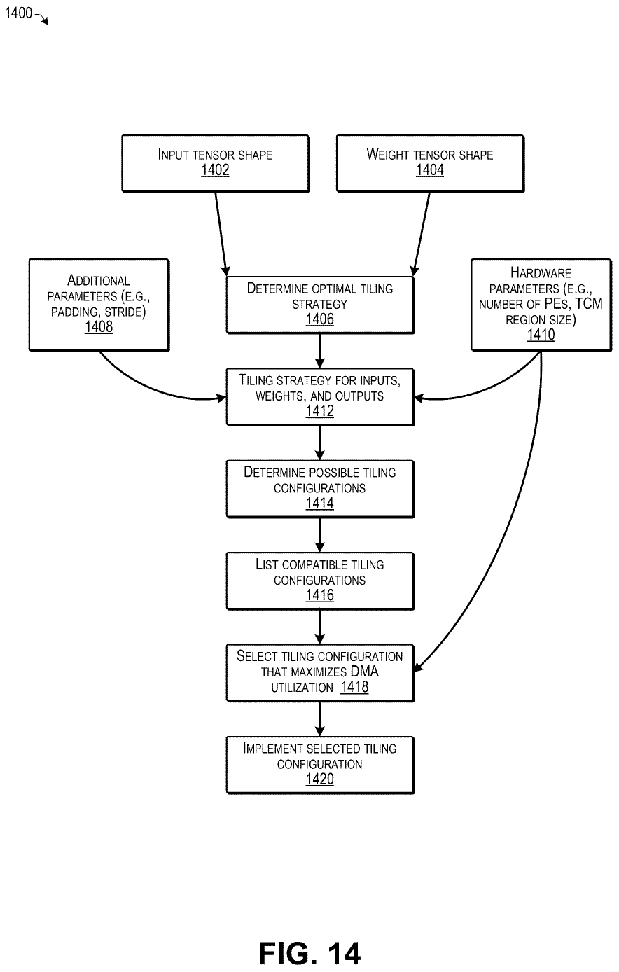

Each vehicle ECU 104 may include one or more processors 116, which may include one or more of system-on-chip (SoC) processors, central processing units (CPUs), graphics processing units (GPUs), microprocessors, microcomputers, microcontrollers, digital signal processors, state machines, logic circuits, and/or any devices that manipulate signals based on operational instructions. As one example, the processor(s) 116 may include one or more hardware processors and/or logic circuits of any suitable type specifically programmed or configured to execute the algorithms and other processes described herein. The processor(s) 116 may be configured to fetch and execute computer-readable instructions stored in the computer-readable media 118, which may program the processor(s) 116 to perform the functions described herein. Additionally, an example configuration of a SoC that may be used in some implementations of a vehicle ECU 104 herein is described below with respect to FIG. 14.

The computer-readable media 118 may include volatile and nonvolatile memory and/or removable and non-removable media implemented in any type of technology for storage of information, such as computer-readable instructions, data structures, programs, program modules, and other code or data. For example, the computer-readable media 118 may include, but is not limited to, RAM, ROM, EEPROM, flash memory or other memory technology, optical storage, solid state storage, magnetic disk, network-attached storage, cloud storage, or any other medium that can be used to store the desired information and that can be accessed by a computing device. Depending on the configuration of the vehicle ECU(s) 104, the computer-readable media 118 may be a tangible non-transitory medium to the extent that, when mentioned, non-transitory computer-readable media exclude media such as energy, carrier signals, electromagnetic waves, and/or signals per se. In some cases, the computer-readable media 118 may be at the same location as the vehicle ECU 104, while in other examples, a portion of the computer-readable media 118 may be remote from the vehicle ECU 104.

The computer-readable media 118 may be used to store any number of functional components that are executable by the processor(s) 116. In many implementations, these functional components comprise instructions or programs that are executable by the processor(s) 116 and that, when executed, specifically program the processor(s) 116 to perform the actions attributed herein to the vehicle ECU 104. Functional components stored in the computer-readable media 118 may include the vehicle control program 124 and the recognition program 126, each of which may include one or more computer programs, applications, executable code, or portions thereof. Further, while these programs are illustrated together in this example, during use, some or all of these programs may be executed on separate vehicle ECUs 104. Alternatively, in some examples, each of these programs 124 and 126 may be part of a single program.

In addition, the computer-readable media 118 may store data, data structures, machine-learning models, and other information used for performing the functions and services described herein. For example, the computer-readable media 118 may store sensor configuration information 128 that includes information about the sensor type, field of view, detection resolution, detection range and other capabilities, current status and operability, and so forth, of the sensors 112 on board the vehicle 102. Further, the computer-readable media 118 may store vehicle configuration information 130 that includes information about the vehicle 102, such as vehicle ECU configuration, powertrain configuration information, suspension information, tire information, as well as vehicle brand, model, year, trim level, and the like. Additionally, the computer-readable media 118 may store, at least temporarily, sensor data 132 received from the onboard cameras and other sensors 112, and which may also include information about obstacles and landmarks detected during a trip, vehicle location information, and so forth.

Further, while the functional components, data and data structures are illustrated together in this example, during use, some or all of these elements may be stored on or by separate ones of the vehicle ECU(s) 104. The computer-readable media 118 may also include or maintain other functional components and data, which may include programs, drivers, etc., and the data used or generated by the other functional components. Further, the computer-readable media 118 may include many other logical, programmatic, and physical components, of which those described above are merely examples that are related to the discussion herein.

The one or more communication interfaces 120 may include one or more software and hardware components for enabling communication with various other devices, such as over the CAN bus, over the one or more network(s) 106, over the air with the RSUs 103, and, in some cases, with other vehicles. For example, the communication interface(s) 120 may enable communication through one or more of a LAN, the Internet, cable networks, cellular networks, wireless networks (e.g., Wi-Fi) and wired networks (e.g., CAN, Fibre Channel, fiber optic, Ethernet), direct connections, as well as close-range communications such as BLUETOOTH®, vehicle-to-vehicle, and the like, as additionally enumerated elsewhere herein.

The sensor data 132 may include images received from the cameras. In addition, in the case that sensors 112 include sensors other than cameras, the sensor data 132 may include sensor data received from the various other onboard sensors such as radar, lidar, ultrasound, a global navigation satellite system (GNSS) receiver (referred to hereinafter as a satellite positioning system receiver), accelerometers, a compass, and the like. In addition, the sensor data 132 that is used by the vehicle control program 124 may include information received from or associated with various vehicle systems 114, such as (not shown in FIG. 1) from a suspension controller associated with the suspension system, a steering controller associated with the steering system, a vehicle speed controller associated with a braking and acceleration system, and so forth.

The vehicle control program 124 may use rule-based and/or artificial-intelligence-based control algorithms, or any combination thereof, to determine parameters for vehicle control. For instance, the vehicle control program 124 may determine an appropriate action, such as braking, steering, accelerating, or the like, and may send one or more control signals to one or more vehicle systems 114 based on the determined action. For example, the vehicle control program 124 may send control signals to the suspension controller, the steering controller, and/or the vehicle speed controller for controlling or partially controlling the vehicle in some applications.

One or more human-machine interfaces 122 may include any suitable type of input/output devices, such as buttons, knobs, joysticks, touchscreens, speakers, microphones, voice recognition and artificial speech technology, in-cabin sensors, such as eye monitoring cameras, vital sign monitors, and so forth. As one example, a vehicle occupant may use a human-machine interface 122 to indicate a destination location, such as via voice command or touchscreen inputs. Implementations herein are not limited to any particular type of human-machine interfaces 122.

Furthermore, the vehicle ECU 104 may include, or may have associated therewith, one or more cooling devices 134. For instance, in some cases, the cooling device(s) 134 may include both air-cooling devices and liquid cooling devices. As one example, an air cooling device may include a fan to move air over one or more surfaces of the vehicle ECU. More particularly, in some cases, the air cooling device may move air over a SoC portion of the ECU, such as over the processor(s) and other components of the SoC. In some examples, the air cooling device may include one or more fans operable at at least two different speeds depending on the amount of cooling need to lower the temperature to maintain a desired temperature. Thus, one cooling technique for reducing the thermal load on the vehicle ECU may include operating the air cooling fan at a first operating speed, and second cooling technique may include operating the air cooling fan at a second operating speed that is different from the first operating speed.

Additionally, in the case that the vehicle ECU includes liquid cooling, this may provide an alternative cooling technique that may typically bring down the thermal load faster, but with lower energy efficiency during operation. As one example, a liquid cooling system may include a first heat exchanger in contact with the SoC to receive heat from the SoC, and transfer the heat to a liquid. The heated liquid is circulated to a second heat exchanger for exhausting the heat from the liquid.

The service computing device(s) 108 may include one or more servers or other types of computing devices that may be embodied in any number of ways. For instance, in the case of a server, the programs, other functional components, and data may be implemented on a single server, a cluster of servers, a server farm or data center, a cloud-hosted computing service, and so forth, although other computer architectures may additionally or alternatively be used.

Further, while the figures illustrate the functional components and data of the service computing devices 108 as being present in a single location, these components and data may alternatively be distributed across different computing devices and different locations in any desired manner. Consequently, the functions may be implemented by one or more service computing devices, with the various functionality described herein distributed in various ways across the different computing devices. Multiple service computing devices 108 may be located together or separately, and organized, for example, as virtual servers, server banks, and/or server farms. The described functionality may be provided by the servers of a single entity or enterprise, or may be provided by the servers and/or services of multiple different entities or enterprises.

In the illustrated example, each service computing device 108 may include one or more processors 140, one or more computer-readable media 142, and one or more communication interfaces 144. Each processor 140 may be a single processing unit or a number of processing units, and may include single or multiple computing units or multiple processing cores. The processor(s) 140 can be implemented as one or more microprocessors, microcomputers, microcontrollers, digital signal processors, central processing units, graphics processing units, AI processors, SoCs, state machines, logic circuitries, and/or any devices that manipulate signals based on operational instructions. For instance, the processor(s) 140 may be one or more hardware processors and/or logic circuits of any suitable type specifically programmed or configured to execute the algorithms and processes described herein. The processor(s) 140 can be configured to fetch and execute computer-readable instructions stored in the computer-readable media 142, which can program the processor(s) 140 to perform the functions described herein.

The computer-readable media 142 may include volatile and nonvolatile memory and/or removable and non-removable media implemented in any type of technology for storage of information, such as computer-readable instructions, data structures, program modules, or other data. Such computer-readable media 142 may include, but is not limited to, RAM, ROM, EEPROM, flash memory or other memory technology, optical storage, solid state storage, magnetic tape, magnetic disk storage, storage arrays, network-attached storage, storage area networks, cloud storage, or any other medium that can be used to store the desired information and that can be accessed by a computing device. Depending on the configuration of the service computing device 108, the computer-readable media 142 may be a type of computer-readable storage media and/or may be a tangible non-transitory media to the extent that when mentioned herein, non-transitory computer-readable media exclude media such as energy, carrier signals, electromagnetic waves, and signals per se.

The computer-readable media 142 may be used to store any number of functional components that are executable by the processors 140. In many implementations, these functional components comprise instructions or programs that are executable by the processors 140 and that, when executed, specifically configure the one or more processors 140 to perform the actions attributed above to the service computing device 108. For example, the functional components may together provide a data analytics platform 145 that provides the functions attributed to the service computing devices 108. Functional components stored in the computer-readable media 142 may include a navigation information program 146 that may be executed to configure the service computing device 108 to determine and send navigation information, such as routing information and instructions for thermal management of the vehicle ECU 104 to the vehicle 102. For example, the navigation information program 146 may include one or more descriptive analytics modules 148, one or more predictive analytics modules 150, and one or more prescriptive analytics modules 152, which may be executed for determining an optimal route for the vehicle 102, such as based on determining one or more POZs and predicted thermal loads on the vehicle ECU 104 having a SoC, as well as for performing other functions.

For instance, to realize the benefits of connected vehicle technologies for partially or fully autonomous vehicles, the connected data analytics platform 145 may receive various different types of the data from different sources such as vehicles 102, infrastructure cameras and other sensors, cellphones, other transportation data services, and so forth, as discussed above. The data analytics platform 145 may process the received data to derive value for end users by using various different modules categorized in analytics layers, such as the descriptive analytics module(s) 148, predictive analytics module(s) 150, and prescriptive analytics module(s) 152. The descriptive analytics modules 148 may include multiple modules used for data processing, authentication, data filtering, data fusing, and so forth. The predictive analytics module(s) 150 may be used to predict different features expected for vehicle control, such as vehicle speed, route, anomaly prediction, and the like, such as by employing AI algorithms, simulation programs, and so forth. The prescriptive analytics modules 152 may include AI modules that provide values, control signals, and/or instructions to various end users based on their respective requirements for safety, efficiency, comfort, and the like. Accordingly, the data analytics platform 145 may provide outputs based on user inputs and/or predictions. Furthermore, while three different types of modules are described in the example of FIG. 1, fewer or more types of modules may be employed in other examples of the system herein.

Examples of descriptive analytics modules 148 may include modules that perform communications, determining vehicle FOV, perform authentication, data filtering, data fusion, and candidate route prediction and monitoring. Examples of predictive analytics modules 150 may include destination prediction, candidate route prediction and monitoring, determining a precautionary observation zone, speed profile determination, determining VEC locations, determining predicted ECU and SoC usage for candidate routes, and determining predicted ECU temperatures and thermal loads for candidate routes. Examples of prescriptive analytics modules 152 may include modules for determining power management instructions and/or thermal management instructions for a vehicle 102.

In addition, the computer-readable media 142 may store or access data used for performing the operations described herein. Further, in some examples, the data may be stored in any suitable type of data structures, such as in one or more databases 154. Examples of databases 154 may include a map data database 156, a time series data database 158, an ECU data database 160, and a vehicle data database 162. For example, the map data database 156 may include information related to a required FOV for selected road segments, road profiles, high definition maps, and standard maps for various geographic regions. Furthermore, the time series data database 158 may include information such as traffic data, weather data, vehicular communication data, vehicle CAN data, sensor data, and so forth. Additionally, the ECU data database 160 may maintain information related to particular vehicle ECU specifications including SoC data for vehicle ECUs 104 that include SoCs. Examples of information maintained in the ECU data DB 160 may include identifying information of virtual models that may be used to model particular SoCs, power usage versus temperature of the SoC for various power usage scenarios, and so forth. In addition, the vehicle data database 162 may include information about each vehicle that uses the system 100, which may include vehicle identification information to use for communicating with and authenticating the vehicle, sensor configuration information 128, vehicle configuration information 130, past destinations of the vehicle or vehicle occupants, information about an owner or other occupant associated with the vehicle, such as an occupant profile including occupant information and preferences, and so forth.

Further, the service computing device 108 may also include or maintain other functional components, data, and databases not specifically shown in FIG. 1, which may include programs, drivers, etc., and the data used or generated by the functional components. Additionally, the service computing device 108 may include many other logical, programmatic, and physical components, of which those described above are merely examples that are related to the discussion herein. Examples of machine-learning models (MLMs) that may be used in some examples of the modules 148, 150 and/or 152 herein, such as for the AI-based algorithms and models, may include artificial neural networks, such as self-organizing neural networks, recurrent neural networks, convolutional neural networks, modular neural networks, and deep-learning neural networks, as well as predictive models, decision trees, classifiers, regression models, such as linear regression models, support vector machines, stochastic models, such as Markov models and hidden Markov models, and so forth.

The communication interface(s) 144 may include one or more interfaces and hardware components for enabling communication with various other devices, such as over the network(s) 106. For example, communication interface(s) 144 may enable communication through one or more of the Internet, cable networks, cellular networks, wireless networks (e.g., Wi-Fi) and wired networks (e.g., fiber optic and Ethernet), as well as close-range communications, such as BLUETOOTH®, BLUETOOTH® low energy, DSRC, and the like, as additionally enumerated elsewhere herein.

In addition, the service computing device(s) 108, and in some cases, the vehicle ECU(s) 104 may be able to communicate over the one or more networks 106 with one or more information source computing devices, such as web servers, service provider computing devices, public databases, private databases, or the like. Information source computing devices illustrated in this example include one or more map provider computing device(s) 164 that may provide map data 166 to the service computing devices 108 and/or to the vehicle ECUs 104. Additionally, one or more OEM (original equipment manufacturer) computing devices 168 may provide OEM information 170 about vehicles that they manufacture and/or may receive information about their vehicles from the service computing devices 108. Further, one or more government computing devices 172 may provide government data 174, such as road information, state department of motor vehicle information, Department of Transportation information, construction information, and so forth.

The information source computing device(s) 164, 168, and 172 may include hardware and software configurations similar to the service computing devices 108 described above, but with different functional components and data stored thereon or associated therewith. Further, while several types of information source computing devices are described herein, numerous other types of information source computing devices may provide information to the service computing devices 108 and/or the vehicle ECUs 104. For example, the information source computing devices may provide local condition data to the service computing device(s) 108 for indicating the current conditions of specified road segments, such as with respect to weather conditions, traffic, road closures, special events, and so forth.

In addition, a user computing device 180 may execute one or more user applications 182 for providing information and/or instructions to the service computing device 108. For instance, the user computing device 180 may be a mobile device such as a cell phone, smart phone, tablet, wearable device, laptop, or the like that may be used to communicate directly with the service computing device 108 over the one or more networks 106. As one example, the user application 182 may include a browser and the user may use the browser to interact with the service computing device 108 such as for setting preferences, providing information about the vehicle 102, providing information about the user, or the like, via a web application, website, or other suitable user interface.

The VEC(s) 105 may include one or more processors 190, one or more computer readable media 192, and or more communication interfaces 194. The one or more processors 190 may correspond to any of the processors 140 discussed above with respect to the service computing devices 108. The computer readable media 192 may correspond to any of the computer readable media 142 discussed above with respect to the service computing devices 108. The communication interfaces 194 may correspond to any of the communication interfaces 144 discussed above with respect to the service computing devices 108.

The computer readable media 192 of the VEC 105 may include functional components and data different from that included in the service computing devices 108. For instance, in this example, the VEC 105 includes a data processing program 196 that may perform data processing on behalf of the vehicle ECUs 104. The data processing program 196 may further manage scheduling of a plurality of vehicles 102 received from the service computing devices 108 for communicating with the respective vehicles 102 when within a threshold radio communication range of the respective VEC 105.

In some examples herein, the vehicle ECU 104 may provide, to the service computing device 108, source and destination information 184 for a trip. For example, the vehicle control program 124 or other suitable program may be executed by the vehicle ECU 104 to send to the service computing device 108 the source location and destination location for a desired trip. In addition, the vehicle ECU 104 may provide the sensor configuration information 128 and/or the vehicle configuration information 130 to the service computing device 108 if the service computing device 108 does not already possess this information in the vehicle data database 162. Alternatively, in other examples, the vehicle ECU 104 may merely provide source location information to the service computing device 108 and may request a route from the service computing device 108. In response, the service computing device may predict a destination location, such as based on a current time, current location, and an analysis of past trips made by the vehicle 102. As still another example, the service computing device 108 may send a communication to cause the human machine interface 122 to query a vehicle occupant as to a destination location.

As discussed in additional detail below, the service computing device 108 may execute the navigation information program 146 to determine an optimal route for the vehicle 102 from the source location to the destination location. For example, the service computing device may execute the descriptive analytics module(s) 148, the predictive analytics module(s) 150, and the prescriptive analytics module(s) 152 to determine an optimal route based on s determination of one or more POZs for one or more candidate routes, and further based the computational requirements and the vehicle ECU thermal management requirements associated with each of the determined POZs. As mentioned above, due to the requirements for large amounts of data processing to be performed in real-time for autonomous and semi-autonomous driving, the vehicle ECU 104 may include a SoC that uses a large amount of power for processing sensor data and determining how to control the vehicle. The large power consumption generates heat in the vehicle ECU 104, which requires effective thermal management through one or more cooling arrangements. Implementations herein predict the power consumption of the vehicle ECU SoC and determine appropriate thermal management for the vehicle ECU 104 to ensure reliable operation of the vehicle ECU 104 having the SoC. For example, the service computing device 108 may estimate the utilization of the vehicle ECU SoC for an entire candidate route in advance using a virtual model and precautionary observation zones (POZs) as mentioned above, which helps to ensure the reliability, efficiency, and performance of the vehicle ECU when traversing the route.

Examples herein are able to provide an improvement in energy efficiency through thermal management of the SoC of the vehicle ECU 104, which can increase the overall efficiency of the vehicle 102. For instance, examples herein are able to estimate the usage of the SoC to predict its thermal load (e.g., temperature) in advance for effective thermal management. Techniques herein are able to predict the utilization of the SoC for the entire route in advance for realizing effective thermal management of the vehicle ECU 104. The techniques herein may be used for both connected and standalone automated vehicle ECUs 104. In some examples, at the beginning of a trip, the vehicle 102 shares its current location, destination, sensor specifications, vehicle ECU specifications, etc., with the data management platform 145 provided by the service computing devices 108, or, in other examples, provided by the vehicle ECU 104 itself. Once the destination has been selected, the system determines the optimal route based at least on the user input and/or historic database. The selected route may be divided into road segments, and POZs are determined for each road segment of the selected route. For example, a POZ may be defined as a region that a vehicle should monitor during traversal of that road segment to enable fully autonomous driving functionality. In some examples, the POZ may be a 3D region or volume that varies depending on the road type and waypoint locations. After a POZ is determined for each road segment, the system may determine specific sensors and their field of view, and also may determine a corresponding deep neural networks (DNN) model or other machine-trained model that may be used to recognize obstacles and other necessary road features for each road segment of the selected route. Additionally, selected sensor input information (e.g., the size and resolution of a captured image in the case that the sensor is a camera) is input to the machine-trained model, which is executed using a virtual model of the SoC to predict the usage of the SoC at each POZ, with includes predicting usage of AI accelerator features including MAC operation, memory usage, time consumption, etc. to estimate the usage of AI accelerators for each road segment. The virtual model calculation provides the amount of usage of the SoC for each road segment in advance which can be used to predict a temperature of the SoC at each road segment for determining an appropriate thermal management scheme of the vehicle ECU 104 while the vehicle 102 traverses the selected route.

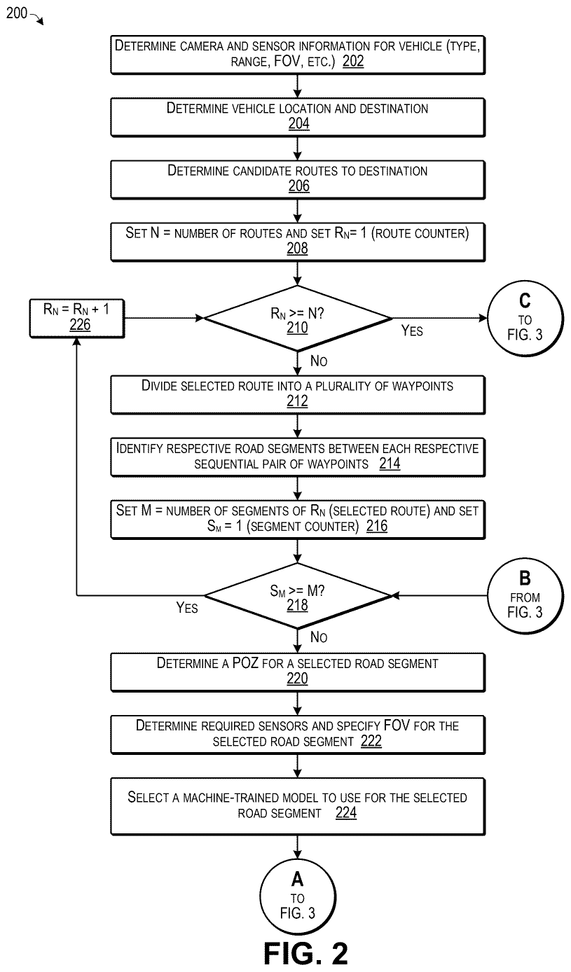

FIGS. 2, 3, 5, 6, 9, 14, and 15 include flow diagrams illustrating example processes according to some implementations. The processes are illustrated as collections of blocks in logical flow diagrams, which represent a sequence of operations, some or all of which can be implemented in hardware, software or a combination thereof. In the context of software, the blocks may represent computer-executable instructions stored on one or more computer-readable media that, when executed by one or more processors, program the processors to perform the recited operations. Generally, computer-executable instructions include routines, programs, objects, components, data structures, and the like, that perform particular functions or implement particular data types. The order in which the blocks are described should not be construed as a limitation. Any number of the described blocks can be combined in any order and/or in parallel to implement the process, or alternative processes, and not all of the blocks need be executed. For discussion purposes, the processes are described with reference to the environments, systems, and devices described in the examples herein, although the processes may be implemented in a wide variety of other environments, systems, and devices.

FIG. 2 is a flow diagram illustrating an example process 200 for determining thermal management techniques to employ for a vehicle ECU during a trip according to some implementations. In some examples, the process 200 may be executed by the system 100 discussed above. For example, the process 200 may be executed by the service computing device 108 executing the navigation information program 146. Alternatively, as mentioned above, in other examples, the process 200 may be executed at least in part by at least one of a VEC 105 or the vehicle ECU 104. For instance, in the case of a connected vehicle that is in communication with the one or more networks 106, the process 200 may be executed by the service computing device 108 (or VEC 105), whereas in the case of a vehicle 102 without a network connection, the process 200 may be performed by the vehicle ECU 104.

At 202, the service computing device may determine camera and sensor information, and ECU specifications for the vehicle. For example, the service computing device may receive the camera and sensor information and ECU specifications from the vehicle for determining the types of cameras and other sensors, number of cameras and other sensors, ranges, FOVs, resolutions, ECU type and specifications, and so forth. As another example, the service computing device may receive an identity of the vehicle and may retrieve camera and sensor information, and other vehicle information, such as ECU specifications, from the vehicle data DB 162 discussed above with respect to FIG. 1.

At 204, the service computing device may determine the vehicle start location and destination, such as by receiving one or more communications from the vehicle. For instance, at the start of a trip, the vehicle 102 may share its location and destination before or after sharing the camera/sensor information, ECU specifications, etc. with the service computing devices 108.

At 206, the service computing device may determine candidate routes between the start location and the destination. For example, a routing and monitoring algorithm may be executed in either the descriptive analytics layer or the predictive analytics layer, as discussed additionally below.

At 208, the service computing device may initialize a first loop by setting a first variable N=number of routes, e.g., representative of the total number candidate routes, and setting a second variable R_{N}=1, e.g., as a counter representative of the candidate route currently selected for processing.

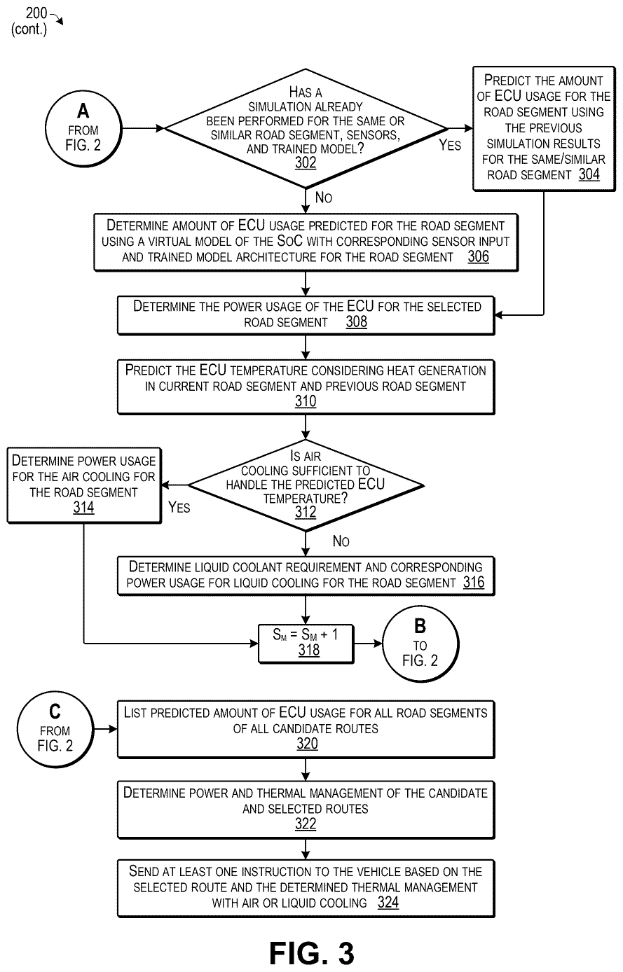

At 210, the service computing device may determine whether the value of R^{N} is greater than or equal to the value of N. If not, the process goes to block 212 to evaluate a candidate route. If so, all of the candidate routes have been evaluated and the process goes to block 320 of FIG. 3.

At 212, the service computing device may divide the selected route into a plurality of waypoints. As one example, the waypoints may be defined in advance on a high definition map or a standard map that may be stored in the map data database 156.

At 214, the service computing device may identify respective road segments between each respective sequential pair of waypoints. The length of each road segment between each pair of waypoints may vary from a few centimeters to several hundred meters.

At 216, the service computing device may initialize a nested second loop by setting a third variable M=number of segments of R_{N}, and setting a fourth variable S_{M}=1, e.g., as a counter representative of the segment currently selected for processing.

At 218, the service computing device may determine whether S_{M} is greater than or equal to M. If not, the process goes to block 220 to evaluate a road segment of the candidate route. If so, all the road segments for the route have been evaluated, and the process goes to block 226 to increment R_{N} and begin processing the next candidate route, if any.

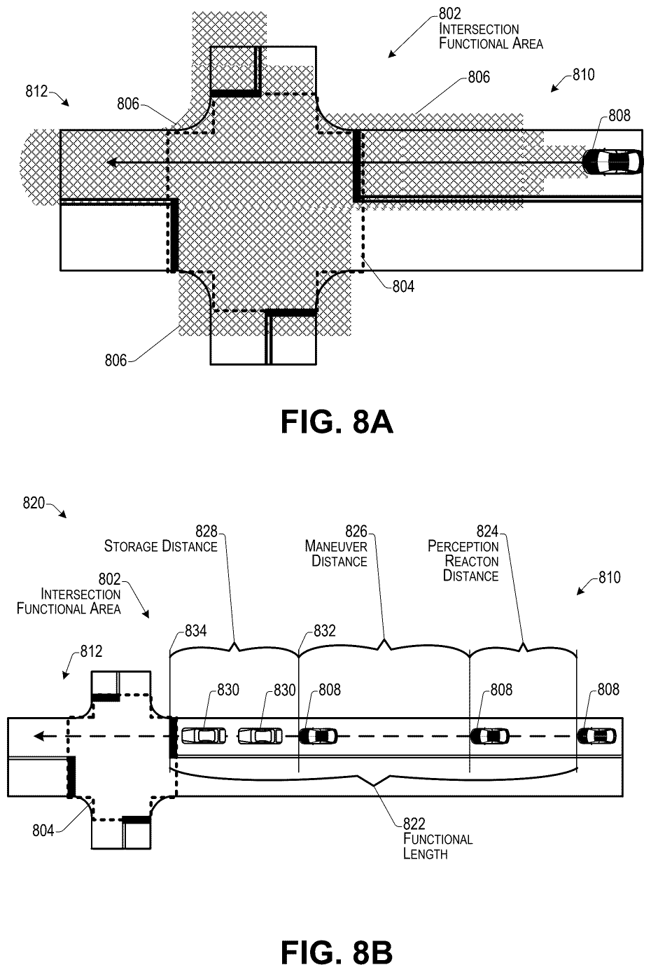

At 220, the service computing device may determine a POZ for the selected road segment. Examples of how to determine a POZ are discussed below, e.g., with respect to FIGS. 8-11. In some examples, a POZ may include an area of potential obstacle, a sign, or the like, that an automated vehicle should monitor using its onboard sensors for avoiding collision, meeting regulations, and/or ensuring safety. For example, a fully automated vehicle may be expected to monitor the entire POZ of a road segment during traversal of the road segment to enable the vehicle's fully automated driving functionalities.

At 222, based on the POZ for the road segment, the service computing device may determine required sensors and specify the sensor FOV for monitoring the POZ for the selected road segment.

At 224, the service computing device may select a machine-trained model (e.g., a DNN) to use for the selected road segment. For example, different machine-trained models can be used for different sensors or different sensor fusion systems for an automated vehicle. Accordingly, the computing device determines the machine-trained model(s) that need to be executed for the selected road segment. The process then continues at block 302 of FIG. 3.

At 226, when the value of S_{M} is greater than or equal to M at block 218, all of the segments in the candidate route have been processed and the computing device increments R_{N} by one and goes to block 210 to determine whether there are any remaining candidate routes to process. If not (i.e., R_{N}=N), the process goes to block 320 of FIG. 3.

FIG. 3 is a flow diagram that illustrates a continuation of the process 200 of FIG. 2 according to some implementations.

At 302, following block 224 of FIG. 2, the service computing device may determine whether a calculation has already been performed for the same or similar road segment, sensors, and trained model. For example, determining the SoC usage for every road segment for the corresponding sensor(s) input and trained model(s) is time consuming. Accordingly, if a similar simulation as already been performed for the same or similar road segment POZ, and for the same or similar sensors and SoC, then the results of the previous simulation may be used rather than executing a new simulation for the SoC, trained model, POZ, and sensor FOV for the current road segment and vehicle. If so, the process goes to 304. If not, the process goes to 306.

At 304, when there is already a simulation result for the same or similar road segment, sensors, SoC, and trained model(s), the service computing device may predict the amount of vehicle ECU/SoC usage for navigating the road segment currently being analyzed using the previous simulation result for the same/similar road segment. For instance, to operate the vehicle as a fully automated vehicle, the vehicle's cameras and/or other sensors should have the field of view (FOV) to capture the POZ of the corresponding road segment. In the case that the vehicle camera or other sensors cannot cover the POZ for a selected road segment, the service computing device may check for additional data (e.g., data from infrastructure sensors, sensors on other vehicles, or other sensors) that may be obtained and processed by a VEC to provide navigational information (e.g., objects, traffic, signs, signals, road anomalies, or the like) to the vehicle 102.

At 306, the service computing device may determine the amount of ECU usage predicted for the road segment using a virtual model of the SoC with corresponding sensor input and trained model architecture for the road segment. For example, the computing device may determine the SoC usage using virtual models of the SoC with corresponding sensor input and DNN or other trained model architecture. Note that the ECU can consist of single or multiple SoCs.

At 308, the service computing device may determine the power usage of the vehicle ECU for the selected road segment.

At 310, the computing device may predict the ECU temperature considering heat generation in the current road segment based on the power usage determined at 308 and further based in part on the temperature of the ECU determined for the previous road segment. As an example, the computing device may employ a lookup table or a machine-trained model to predict the temperature based on the amount of SoC usage.

At 312, the service computing device may determine whether air cooling is sufficient to handle the predicted ECU temperature. If so, the process goes to 314. If not, the process goes to 316. For example, to determine whether air cooling is sufficient, the computing device may access a lookup table or use a machine-trained model to predict whether a particular air cooling system can keep the SoC within a desired temperature range.

At 314, when the computing device determines that air cooling is sufficient, the service computing device may predict power usage for operating the air cooling system while the vehicle traverses the selected road segment.

At 316, when the computing device determines that air cooling is insufficient to maintain the SoC within a desired temperature, the service computing device may determine a liquid coolant requirement for cooling the SoC and may further determine a corresponding power usage for operating the liquid cooling system while the vehicle traverses the road segment.

At 318, the service computing device may increment the segment counter S_{M} by a value of one and return to block 218 of FIG. 2. For example, the process of blocks 212-224 and 302-318 may be repeated until all road segments in a selected candidate route have been analyzed.

At 320, following execution of block 210 of FIG. 2, and determination that the last candidate route has been processed, the service computing device may list a predicted amount of ECU usage for all road segments of all candidate routes.

At 322, the service computing device may determine power and thermal management of the candidate routes, such as to enable comparison and selection of a route that enables more efficient use of cooling systems for cooling the vehicle ECU.

At 324, the service computing device may select one or more optimal routes based at least in part on determining a route that enables the more efficient cooling of the vehicle ECU, such as by the use of air cooling as opposed to the use of liquid cooling. Furthermore, some examples may also consider an amount of autonomous driving available for each respective candidate route when selecting a route. For instance, the optimal route selected may be the route that ensures that fully automated driving is available for maximizing autonomous driving. Further, in some cases, other factors considered may include total driving time to the destination, vehicle occupant comfort, amount of fuel/energy predicted to be consumed by the vehicle when traversing the respective route, or the like. In some examples, the service computing device may send one or more instructions to the vehicle to cause the vehicle to begin traversal of the selected route and to further cause the vehicle to operate the cooling system for the SoC using the cooling system determined to be optimal for each road segment.

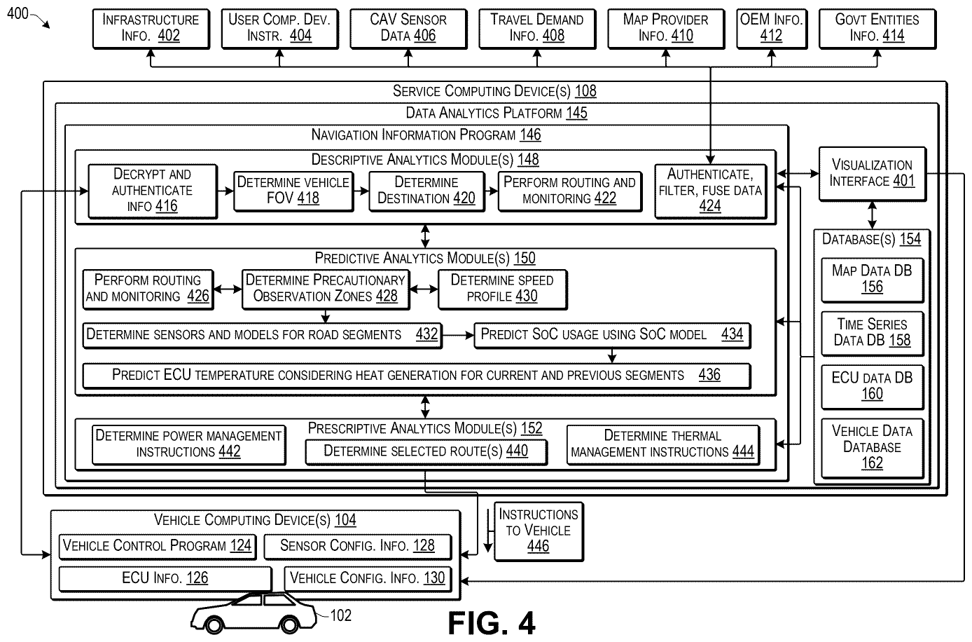

FIG. 4 is a combined flow diagram and block diagram illustrating an example architecture and process 400 for determining a route for a vehicle that takes thermal management of a vehicle ECU into consideration according to some implementations. For instance, the example of FIG. 4 includes a detailed system architecture and data flow that may be used to determine a route for a vehicle that takes into consideration efficiency of thermal management of a vehicle ECU. For example, the architecture of FIG. 4 may determine POZs for road segments along one or more candidate routes and while taking into consideration a vehicle's onboard sensor configuration, vehicle powertrain configuration, vehicle ECU/SoC configuration, and other vehicle configuration information. In some cases, the architecture of FIG. 4 may correspond to the system 100 discussed above with respect to FIG. 1.

In this example, the data analytics platform 145 receives the data from different sources such as vehicles, infrastructure sensors, cellphones, web servers of fleet companies, insurance providers, government entities (state DMVs, federal entities, etc.), other transportation data services, and so forth. The data analytics platform 145 may process the received data to derive values for end users by using different artificial intelligence (AI) modules categorized in different analytics layers, including the descriptive analytics modules 148, the predictive analytics modules 150, and prescriptive analytics modules 152, as well as databases 154 and a visualization interface 401. Further, the data analytics platform 145 is able to share vehicle data with other third parties such as OEMs and may ingest data from third parties, such as map providers, into the data analytics platform 145.

In some examples, a portion of the process described may be executed by the vehicle ECU(s) 104, and another portion of the process may be executed by the service computing device(s) 108 or the VECs 105. Furthermore, while in this example, certain functions are being illustrated as being performed by one or the other of the computing devices 104, 105, or 108, respectively, it will be readily apparent to those of skill in the art having the benefit of the disclosure herein that some of the functions may be performed by other ones of the computing devices 104, 105, or 108.

The service computing device(s) 108 hosting the data analytics platform 145 may receive various types of information from various different sources and also may provide data to one or more of the sources. Examples include infrastructure information 402, user computing device instructions 404, connected automated vehicle (CAV) sensor data 406, travel demand information 408, map provider information 410, OEM information 412, and government entity information 414. As mentioned above, the infrastructure information 402 may include infrastructure camera images, and other information about infrastructure, road conditions, construction projects, and the like. Furthermore, the user computing device instructions 404 may include user preferences, user information, vehicle information, and the like, received through a user computing device such as through a website or web app interface. Furthermore, the CAV sensor data 406 may include data received directly from vehicle sensors of connected autonomous vehicles, such as connected sensors that automatically transmit data from the vehicle 102 to the service computing device 108.

The travel demand information 408 may provide an indication of possible road crowding based on current and expected demand, which may be based in part on scheduled holidays, air travel and rail travel ticket sales, sporting events and other types of event sales, and so forth. The map provider information 410 may include high definition and low definition maps as well as other information such as traffic data and the like. The OEM information 412 may provide various information about vehicles produced by particular OEMs such as powertrain information, fuel efficiency, and so forth. The government entity information 414 may indicate government provided safety information, traffic sign information, road construction information, road closure information, and so forth. In some examples, one or more data exchange application programing interfaces (APIs) may be employed for exchanging data with the above-discussed entities, such as for receiving data from the above-discussed entities or sending data to the above-discussed entities. Further, the above-discussed entities are only examples of entities with which information may be exchanged, or from which information may be received, and numerous other information entities will be apparent to those of skill in the art having the benefit of the disclosure herein.

As mentioned above with respect to FIG. 1, the databases 154 may include a map data database 156, a time series data database 158, an image data database 160, and a vehicle data database 162. Examples of information that may be maintained in the map data database 156 may include a map of the required FOV for candidate routes, a road profile map or other road profile information, a high definition map of a region in which the vehicle is located, and a standard map of the region in which the vehicle is located. Examples of information that may be included in the time series data database 158 may include information received through the vehicle CAN, vehicle sensor data, traffic data, weather data, and vehicle-to-everything (V2X) data. Examples of information that may be included in the automated vehicle disengagement history database 160 may include information about vehicle disengagement occurrences at various intersections or other road locations. Examples of information that may be maintained in the vehicle data database 162 may include information about individual vehicles such as the vehicle sensor configuration information, vehicle ECU information, vehicle configuration information, vehicle occupant information, history, and preferences, and the like.

Furthermore, at the beginning of a trip, or at any point prior, the vehicle 102 may send, to the service computing device 108, encrypted information about onboard sensor configuration information 128, as well as vehicle configuration information 130, such as powertrain and chassis specification, and may further send ECU information 126 that provides information about the vehicle ECU, including any SoCs. In some examples, the vehicle 102 may send this information to the service computing device 108 using a broadcasting protocol such as MQTT, UDP, or the like. Additionally, in some cases, the vehicle 102 may send source location information, such as a current location, and destination location information to the service computing device 108.

At 416, in the data analytics platform 145, the descriptive analytics module(s) 148 may decrypt the received vehicle data such as by using cryptographic hash algorithms such as MD5, SHA-1, SHA256, or any other decryption techniques. Following decryption, the descriptive analytics module(s) 148 may authenticate or otherwise determine the identity of the vehicle and an occupant. For instance, the authentication process may confirm the data has been received from the correct connected vehicle 102 and may validate the integrity of the received data. In addition, the descriptive analytics module(s) 148 may access the vehicle data database 162 to retrieve any information about the vehicle or occupant maintained in the vehicle data database 162. Examples of information that may be retrieved may include the vehicle sensor configuration information 128 and/or vehicle configuration information 130 and ECU information 126, which may have been previously received for the vehicle 102, as well as user preferences, routing preferences, etc., for an owner of the vehicle or other occupant of the vehicle. Additionally, although not shown in FIG. 4 for clarity of illustration, other processes performed by the data analytics module(s) 148 may include data parsing, data fusion, and the like. For example, a data parsing process may parse an incoming message from the vehicle 102 to a JSON format for further processing, which may include detecting and correcting any corrupt messages sent from the vehicle 102. Further, a data filtering and fusion process may preprocess the data transmitted from the vehicle and update the databases 154 accordingly.

At 418, the descriptive analytics module 148 may determine the vehicle FOV from the vehicle sensor configuration information 128. In some examples, the sensor configuration information 128 may be received from the vehicle 102, while in other examples, the sensor configuration information 128 may be received from the vehicle data database 162. For example, the sensor configuration information 128 may be unlikely to change substantially over time and therefore, having been received previously and stored in the vehicle data database 162, does not need to be transmitted by the vehicle 102 every time a route is to be determined.

At 420, the descriptive analytics module(s) 148 may determine whether a destination location is specified in the received and decrypted vehicle data. If the vehicle destination is available in the decrypted vehicle data, the process goes to 422 to perform routing and monitoring. In some cases, the system may prompt the vehicle occupant for the destination, which may result in the destination being received via voice recognition or other user input. On the other hand, if the vehicle destination is not included in the received information and is not provided by the vehicle occupant, the process may go to 426 to perform the routing and monitoring with prediction of the destination location.

At 422, descriptive analytics module(s) 148 may execute a routing and monitoring algorithm that accepts inputs of vehicle source location, destination location, map, traffic and weather data, and determines candidate routes for the vehicle to reach the destination location. For instance, real-time traffic may be updated using a time loop that executes at a fixed time interval and obtains traffic data from a third party. The traffic data may be ingested in the database and sent to the routing and monitoring algorithm. The routing and monitoring algorithm may be executed by either the descriptive analytics module(s) 148 or the predictive analytics module(s) 150, which may be alternatively invoked based on whether the destination location has been provided or needs to be predicted. If the destination location is not available to the descriptive analytics module(s) 148, the routing and monitoring algorithm may be executed by the predictive analytics module(s) 148 based on use of an AI-based model to predict the destination location, such as by considering the vehicle occupant's history, time of the day, vehicle location, and the like. After the destination location is predicted and, optionally, confirmed by the vehicle occupant, the routing and monitoring algorithm may be executed to generate candidate routes to the destination location as discussed additionally below with respect to 426.

At 424, the descriptive analytics module(s) 148 may further receive the data from the various external sources 402-414, and may perform authentication, filtering, and/or fusing of the received data. For example, the data analytics platform 145 may use data filtering and data fusion to ingest various types of time series and image data obtained from traffic infrastructure, user smartphones, third parties, and so forth. As one example, one or more blockchain networks may be used for exchanging data with at least some of the external sources 402-414. The data may be ingested and stored in the database 154 or the like. As several non-limiting examples, the data may be managed using a combination of SQL (Structured Query Language) and non-SQL databases for achieving superior real-time performance of the data analytics platform 145.

At 426, in the case that the destination location is not included in the received information received from the vehicle 102, the predictive analytics module(s) 150 may predict the destination location, such as by using a machine learning model, a rule-based model, or the like, and/or based on a vehicle occupant profile, historic trip data, time-of-day, and/or other information stored in the vehicle data database 162. The predicted destination may be sent by the service computing device 108 to a voice assistant or other human-machine interface associated with the vehicle ECU 104. As one example, an interactive voice request may be sent to the vehicle occupant for obtaining confirmation of the predicted destination. The predictive analytics module(s) 150 may receive a confirmation of the predicted destination location or a user input that indicates an alternative destination location. Following determination of the destination location, the predictive analytics module(s) 150 may perform routing and monitoring to determine candidate routes between the source location and the destination location.

At 428, after the candidate routes are determined between the source location and the destination location, the computing device may divide the candidate routes into road segments and may determine a POZ for each segment of each candidate route. For example, after the data analytics platform 145 identifies the destination of a connected vehicle, a POZ determination algorithm may be executed to determine an area of a potential obstacle, a sign, a traffic signal, or the like, for each road segment of each of the candidate routes that a fully or partially automated vehicle (which may include a robot, drone, etc.) may need to monitor using its onboard sensors for avoiding a collision, meeting regulations, and ensuring safety. As mentioned above, each candidate route may be divided into multiple road segments, which are the distance between two consecutive waypoints/nodes. Road waypoints or nodes may be defined based on a high definition map or standard map that may be included in the map data database 156. The route waypoints as well as the road segments may be defined by the routing and monitoring process herein. However, determining these features may also be performed by the precautionary observation zone (POZ) process at 428 of FIG. 4. The main task of the POZ process may be to calculate the required observation zone volume for each road segment that an automated vehicle should monitor when traversing a respective road segment.

At 430, the service computing device may determine a speed profile for traversing each road segment and POZ.

At 432, the computing device may further determine sensors and machine-trained models for the road segments. For example different machine-trained models may be used for different road segments and sensor configurations.

At 434, the computing device may predict SoC usage using the sensor configuration, POZ volume, and machine-trained models determined at 432.

At 436, the service computing device may predict ECU temperature considering heat generation for current and previous segments.

At 440, the computing device may determine one or more selected routes for the vehicle to traverse to the destination based at least on the predicted ECU temperatures for the road segments of each candidate route.

At 442, the computing device may determine power management instructions for the selected route(s).

At 444, the computing device may determine thermal management instructions for the selected route(s). For instance, the thermal management instructions may determine a predicted thermal load on the vehicle ECU for each road segment, and may determine a cooling technique for the vehicle ECU for each road segment based at least on the predicted thermal load for each road segment. The instructions sent to the vehicle may include information related to a selected route and at least one selected cooling technique determined for the first route, or more specifically, a respective selected cooling technique to use for each road segment of the selected route. In some cases, the computing device may send instructions to the vehicle to instruct the vehicle to traverse the selected route, and to further instruct the vehicle regarding thermal management procedures, including a cooling technique to use for the vehicle ECU at each road segment as the vehicle traverses the selected route. As mentioned above, the cooling techniques may include air cooling and/or liquid cooling, and the process may be configured to select the most efficient cooling technique that maintains the temperature of the vehicle ECU within a targeted temperature range.

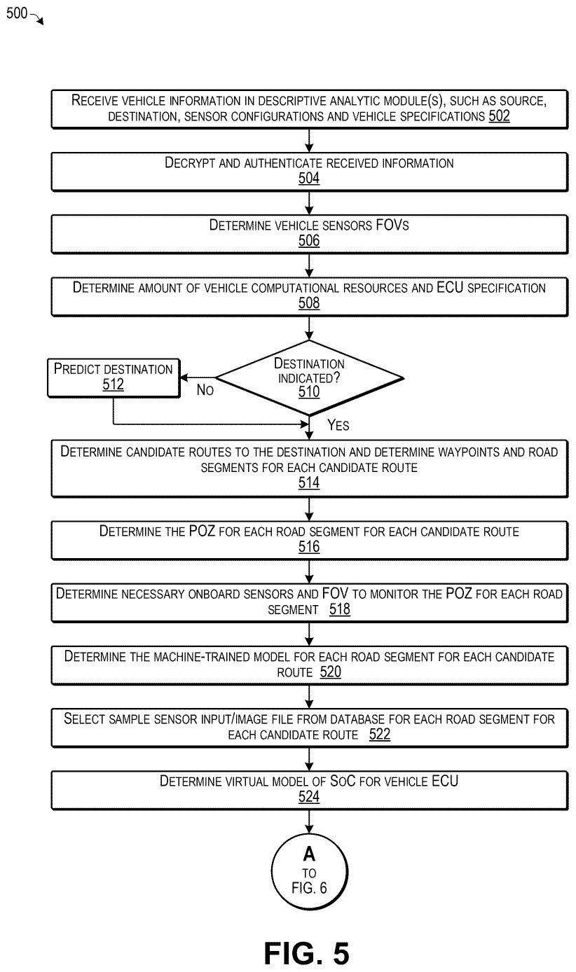

FIG. 5 is a flow diagram illustrating an example process 500 executed by the data analytics platform 145 according to some implementations. In some examples, the process 500 may be executed by the system 100 discussed above. For example, the process 500 may be executed by one or more of the service computing devices 108 executing the navigation information program 146. The process 500 provides additional details to the process 200 discussed above and may be mapped to the data analytics platform 145 discussed above with respect to FIGS. 1 and 4.

For example, the descriptive analytics module(s) 148 of the data analytics platform 145 may decrypt the incoming vehicle data and establish identification of the vehicle and driver by using cryptographic hash algorithms such as MD5, SHA-1, SHA256 and so forth. If the vehicle destination is available in the decrypted vehicle data, then the descriptive analytics module(s) 148 may accept inputs of vehicle location, destination, map, traffic, and weather data, and determine potential routes for the vehicle to reach its destination. Vehicle sensor specifications are used to identify the Field of View (FOV) of the vehicle, which may be used for routing. In case the destination of the connected vehicle is not specified by the system/driver, the predictive analytics module(s) 150 may predict the vehicle's destination, such as by using an AI model based on driver/passenger/vehicle profile, historic trip data, time-of-day, and so forth, that may be stored in the vehicle data database 162. The predicted destination may be passed to an AI based voice assistant that may send an interactive voice request to driver/passenger for obtaining confirmation of predicted destination. In some examples, the voice assistant may be part of a user interface (UI) that may perform speech-to-text conversion, conversation, and text-to-speech conversion.

In the case that the vehicle driver/passenger/system confirms the destination, confirmation is sent back to the predictive analytics module(s) 150. Otherwise, the data management platform 145 may decide the destination based on the destination predicted by the predictive analytics module(s) 150. The predictive analytics module(s) 150 may further receive real-time traffic and confirmed destination inputs for route prediction. The real-time traffic may be updated using a time loop that executes at a fixed time interval and obtains traffic data from a third party service. The traffic data may be ingested in the map database 156, and sent to predictive analytics module(s) 150. Once the destination has been finalized either by descriptive analytics module(s) 148 or predictive analytics module(s) 150, potential routes from start to destination are calculated using a routing engine. Calculated potential routes are subsequently sent to the predictive analytics module(s) 150 in the predictive layer to calculate a safety score of the road segment. As discussed with respect to FIGS. 4 and 5, the predictive analytics module(s) 150 may calculate a POZ 3D region for every road segment of the selected routes, which may be a volume that the vehicle sensors are required to monitor to enable safe automated driving functionality. A vehicle action (e.g., Go Straight, Turn Left, Turn Right, Merge, Lane Change (Right/Left/Multiple), or the like) on each road segment may also be calculated at this stage.

After the system determines the POZ for each road segment of each candidate route, sensors and their corresponding FOV that are needed to monitor the defined POZ are selected. For example, the vehicle 102 herein may use multiple redundant sensors to enable and ensure safety for all road and weather conditions. Similarly, multiple machine-trained models, such as DNNs or other models, as discussed above, can be used based on the sensor and output requirement. Thus, after the POZ and corresponding sensors have been determined, the system can select a machine-trained model to use for the particular road segment. Since, the vehicles herein can use different sensors and different sensor fusions with different selections of different sensor's field of views, sample sensor input information considering different scenarios may be stored in at least one of the databases 154 of the data analytics platform 145.

As one example, in the case of an automated vehicle having multiple mono-camera systems, multiple different image files considering different scenarios may be stored in the database. In the next step, based on the selected road segment and corresponding sensor information, the system may select the sensor input image from the database. Consecutively, the virtual model of the SoC used in the vehicle ECU of the vehicle 102 is selected from the ECU data database 160.

The system may then execute the virtual model of the SoC of the vehicle ECU using a selected machine-trained model and one or more input images. To speed up the process, the system may check whether a similar simulation has already been executed for any previous road segments. If so, the system may determine the SoC usage and power usage of the vehicle ECU for that road segment based on the previous simulation. Otherwise, if not, the system first determines the tiling strategies of tensors for the virtual model of the SoC for efficient usage of limited tightly coupled memory of an AI accelerator. Consecutively, the system performs scheduling of operators and tiles as well as creation of executive binary and data flow control for the selected input and machine-trained model. The system next determines the number of AI accelerators needed for determining the power consumption of the SoC, the percentage of MAC (multiplier-accumulator) usage of the available MAC of each AI accelerator, memory utilization, and time consumption. These numbers are finally used to determine the amount of SoC usage. As discussed, e.g., with respect to FIGS. 4 and 5, the system also determines instructions to provide to the vehicle, and possible alternative routes in case the virtual SoC calculation results show that the execution time of a machine-trained model at some road segment along a selected route is more than an allowable time limit threshold. Finally, based on the predicted SoC usage, the system may predict the temperature of the vehicle ECU (e.g., using any of various techniques, such as a lookup table or AI model) and may determine one or more thermal management instructions to send to the vehicle. Example operations of the flow diagram 500 are discussed further below.

At 502, the service computing device may receive vehicle information in the descriptive analytic module(s), such as source location, destination location, sensor configurations, ECU specifications, and vehicle specifications.

At 504, the service computing device may decrypt and authenticate the received information.

At 506, the service computing device may determine vehicle sensor FOVs. For example, specifications for the vehicle cameras and other sensor specifications are sent to the navigation information program 146 to enable the system to determine the FOVs of the vehicle cameras and other sensors.

At 508, the service computing device may determine the amount of vehicle computational resources, such as based at least on receiving the ECU specification information for the vehicle.

At 510, the service computing device may determine whether the vehicle destination was indicated in the received information. If so, the process goes to 514. If not, the process goes to 512. If the vehicle destination is available in the decrypted vehicle data, then the descriptive analytics module(s) accepts inputs of vehicle location, destination, map, traffic and weather data and determines potential routes for the vehicle to reach its destination.

At 512, the service computing device may predict the destination based on prior trips, time of day, day of the week, or the like. Alternatively, an inquiry may be sent to the vehicle occupant.

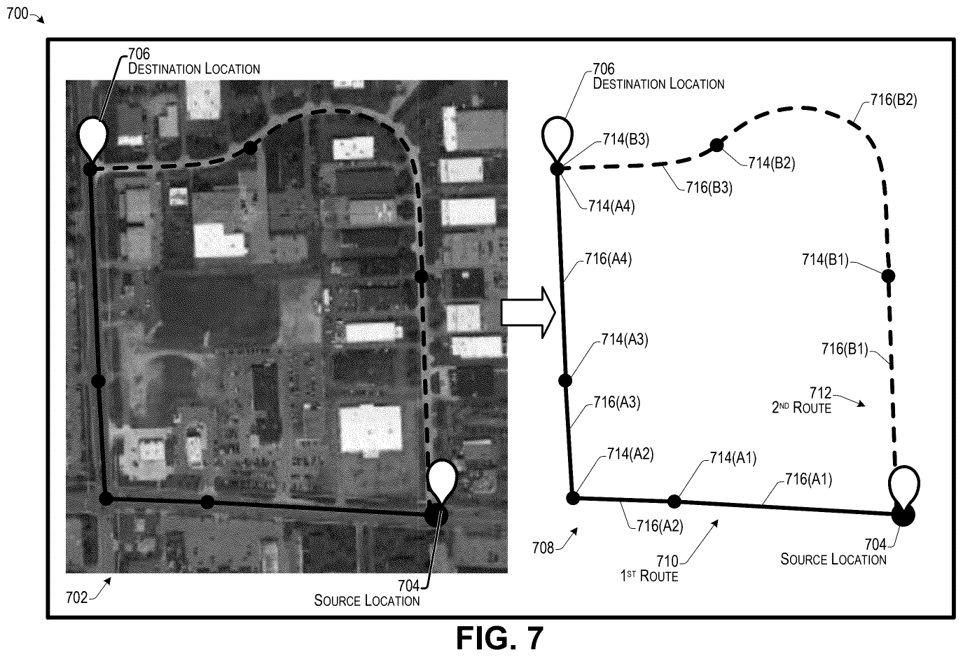

At 514, the service computing device may determine candidate routes to the destination and may determine waypoints and road segments for each candidate route. An example of determining candidate routes is discussed below with respect to FIG. 7. In some cases, the computing device may receive inputs of real-time traffic and confirmed destination inputs for route prediction. The real-time traffic is updated using a time loop that executes at fixed time intervals and obtains traffic data from 3rd parties, this traffic data is ingested in the database and sent to the descriptive analytics module or predictive analytics module. Once the destination has been finalized either by the descriptive or predictive analytics module, candidate routes from start to destination are calculated using a routing engine. The candidate routes are subsequently sent to the POZ determination function in the predictive layer.

At 516, the service computing device may determine the POZ and a safety score for each road segment for each candidate route. An example is discussed below with respect to FIGS. 8-11. For example, the POZ may be the part of the road segment that the automated vehicle needs to monitor when traversing the road segment. The safety score indicates how much percentage of each POZ can be covered by vehicle camera or other sensor FOV. For automated driving, the vehicle FOV should cover the entire POZ. In case the vehicle FOV cannot cover the POZ for a particular road segment, the computing device may determine the time when the vehicle is expected to traverse the particular road segment and communicates with the VEC to the particular road segment to determine whether the VEC will be able to support the vehicle to realize automated driving for that particular road segment.

At 518, the service computing device may determine the onboard sensors and FOV to use for monitoring the POZ for each road segment.

At 520, the service computing device may determine a machine-trained model, such as a DNN, to use for each road segment for each candidate route.

At 522, the service computing device may select a sample sensor input and image file from a database for each road segment for each candidate route.

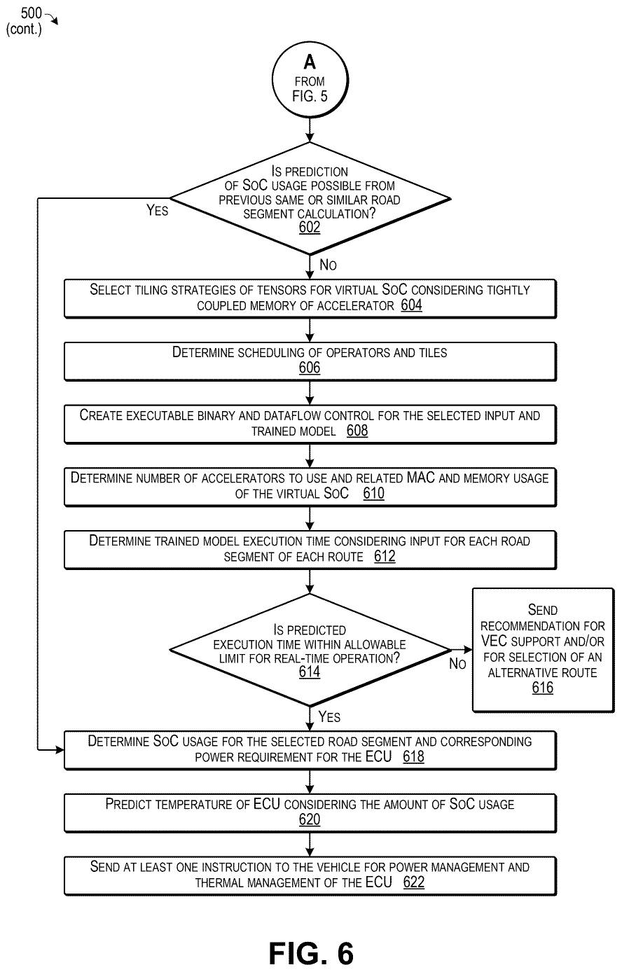

At 524, the service computing device may determine a virtual SoC model that corresponds to the SoC of the vehicle ECU of the vehicle. The process then continues at block 602 of FIG. 6.

FIG. 6 is a flow diagram that illustrates a continuation of the process 500 of FIG. 5 according to some implementations.

At 602, the service computing device may determine whether prediction of SoC usage for a road segment is possible using information from a previous simulation executed for the same road segment or a similar road segment. If so, the process goes to 618. If not, the process goes to 604.

At 604, the service computing device may select tiling strategies of tensors for the virtual SoC considering the tightly coupled memory of an AI accelerator.

At 606, the service computing device may determine scheduling of operators and tiles.

At 608, the service computing device may create an executable binary and data flow control for the selected input and machine-trained model.

At 610, the service computing device may determine the number of accelerators to use and related multiply accumulate (MAC) units and memory usage for the virtual SoC. For instance, examples herein may employ a technique referred to as tensor tiling that splits input data tensors into multiple tiles for efficient data processing. This technique utilizes local data dependencies to maintain intermediate data in on-chip memory that may be tightly coupled to segment the workload.

At 612, the service computing device may determine an execution time for the machine-trained model, taking into consideration an input for each road segment of each route.

At 614, the service computing device may determine whether the predicted execution time for each road segment is within an allowable for enabling real-time operation. If so, the process goes to 618. If not, the process goes to 616.

At 616, when it appears that the predicted execution time is outside an allowable limit for enabling real-time data processing and autonomous vehicle operation, the service computing device may send an instruction for obtaining VEC support and/or for selection of an alternative route.

At 618, on the other hand, when the predicted execution time is within the allowable limit, the service computing device may determine SoC usage for the selected road segment and a corresponding power requirement for the vehicle ECU.

At 620, the service computing device may determine a predicted temperature of the vehicle ECU based at least one consideration of the predicted amount of SoC usage for the selected road segment.

At 622, the service computing device may send at least one instruction to the vehicle for power management and/or thermal management of the vehicle ECU.

FIG. 7 illustrates an example 700 of determining candidate routes between a source location and a destination location according to some implementations. In this example, as shown on a map 702, a source location 704 and a destination location 706 may be initially determined, e.g., as discussed above. For example, after the source location 704 and the destination location 706 have been set, a plurality of feasible candidate routes 708 may be determined. In this example, two feasible candidate routes 708 are illustrated, namely a first route 710 and a second route 712. In other examples, more or fewer candidate routes may be determined. In addition, in the case that there are a very large number of feasible candidate routes, the number of candidate routes may be narrowed using any of various thresholds such as estimated distance traveled along each route, estimated time of travel for each route, or the like. In some cases, the narrowing criteria may be based at least in part on user preferences.

Each route 710 and 712 may be divided into a plurality of segments based on waypoint nodes 714 and intervening road segments 716, which are the distance between two waypoints 714. The locations of the waypoints 714 and the length of each road segment 716 may depend in part on the types of roads to be traversed. For instance, road segments 716 may vary from less than a meter to several hundred meters or more. In some cases waypoints 714 may correspond to intersections however this is not necessarily always the case, such as in the case of long stretches of road that may be broken into shorter road segments despite not having any intersections.

In the illustrated example, the first route 710 is divided into four road segments including waypoints 714(A1), 714(A2), 714(A3), and 714(A4), and road segments 716(A1), 716(A2), 716(A3), and 716(A4). In addition, the second route 712 is divided into three road segments including waypoints 714(B1), 714(B2), and 714(B3), and road segments 716(B1), 716(B2), and 716(B3). As mentioned above, in other examples, a different number of waypoints and road segments might be used for each of the routes 710, 712. Furthermore, while the map 702 is illustrated in FIG. 7 for discussion purposes, in operation it may not be necessary for the service computing device 108 to generate a visual map for performing the identification and analysis of the selected routes and road segments.

The data analytics platform 145 may store data in advance for each waypoint 714 and/or road segment 716 for all candidate routes or at least the most feasible candidate routes within a geographic region. For example, the data analytics platform 145 may analyze maps of geographic regions in advance for determining routes and possible waypoints and road segments on the roads included in each map. This information may be stored in the map data database 156 discussed above with respect to FIGS. 1 and 4 in advance of receiving a request for route guidance from a vehicle.

Furthermore, for the determined road segments 716 identified in each map, the data analytics platform 148 may determine in advance and store the POZ for each respective road segment 716. In this routing example, as discussed additionally below, for the first route 710 and the second route 712, the data analytics platform 145 may execute the POZ determination process in the analytics layer to determine the POZs for each segment of each route 710, 712. The vehicle sensor FOV may be calculated by the data analytics platform 145 based on the vehicle onboard camera and sensor configuration information 128 received by the data analytics platform 145 for the vehicle 102, such as discussed above with respect to FIG. 4. In addition, once the road segments and POZs for each route have been calculated, the data analytics platform 145 may further determine the thermal management technique to use at each of the road segments along a respective route, such as based on the predicted power usage of the vehicle ECU SoC.

FIGS. 8A and 8B illustrate examples of intersections according to some implementations. FIG. 8A illustrates an example intersection 800 according to some implementations. The intersection 800 includes an intersection functional area 802 indicated by cross hatching. The intersection functional area 802 may include the crosshatched region that includes both an intersection physical area 804 of the intersection (indicated by dashed line), and the additional areas 806 outside of the intersection physical area 804 in which a vehicle 808 may maneuver. Thus, the intersection physical area 804 may correspond to the fixed area within the four corners of the intersection 800. On the other hand, the overall functional area 802 may be variable and may include an upstream portion 810 and a downstream portion 812 as shown in FIG. 8B.

FIG. 8B illustrates an example intersection 820 according to some implementations. As mentioned above, contrary to the fixed physical area 804 of the intersection 820, the intersection functional area 802 is variable and includes both upstream portion 810 and downstream portion 812 in addition to the physical area 804. The upstream area 810 of the intersection functional area 802 includes a functional length 822. The functional length 822 may be divided into several portions, such as when a vehicle 808 approaches the intersection 820 and during which the vehicle 808 decelerates and comes to a complete stop. These portions include a perception reaction distance 824 and a maneuver distance 826. In addition, the functional length 822 may include a storage distance 828, which may be a portion of the intersection functional area 802 in which other vehicles 830 are queued.

Realizing safety at intersections may be accorded a high priority as accidents mostly happen at intersections. At the intersection, a human driver may understand where to make the lane changes, when and how to read the traffic light, location to stop, where to watch before making a turn, when and speed to make the turn, etc. An automated vehicle should have the ability to follow the sequential steps and observe the proper region to make human-like decisions. Thus, an automated vehicle should understand the different regions at intersections, such as those specified by government, local authorities, etc., and perform the same action for each region as a human driver would. The intersection functional area calculation may depend on the road speed limit, location, type of road, etc. which may be defined by designated authorities in each country. In the USA, according to the AASHTO (American Association of State Highway and Transportation Officials) intersection functional length (F) is the sum of stopping sight distance(S) plus the storage length distance (Q) as shown in EQ (1). In case there is no traffic, storage length (Q) becomes zero and intersection functional area becomes the stopping sight distance. The stopping sight distance is the combination of the distances traveled by a vehicle during two phases to stop the vehicle, i.e., a first phase is the perception reaction distance 824 traveled during perception reaction time and the second phase is the maneuver distance 826 traveled during a maneuver time:

$$F = S + Q \qquad EQ ( 1 )$$

$$S = ( 1.47 * V * t ) + 1.075 * ( {V}^{2} / a ) \qquad EQ ( 2 )$$

where,
F=Intersection functional length
S=Stopping sight distance
Q=Storage or queue length
V=Design speed (mph)
t=Perception reaction time (2.5 Sec)
a=Deceleration rate (within 11 to 15 ft/sec², e.g., 11.2 ft/sec²).

The first part of EQ (2) indicates the distance covered during the perception reaction time during which the driver traverses the perception reaction distance 826, realizes that a decision is needed, and decides what kind of maneuver is appropriate. The perception reaction time may typically be about 2.5 seconds, which includes about 1.5 seconds for perception and about 1.0 seconds for reaction. The second part of EQ (2) indicates the distance traveled by the driver during the maneuver distance for decelerating the vehicle and coming to a complete stop, e.g., at 832 when there are other cars 803 in the storage distance 828, or at 834 when there are no other cars in the storage distance 828.

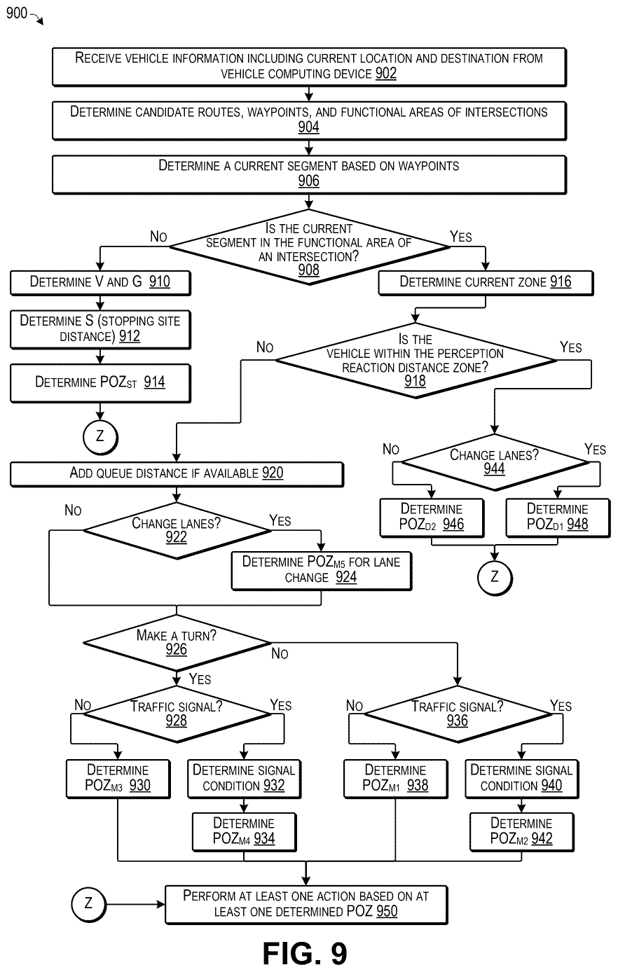

FIG. 9 is a flow diagram illustrating an example process 900 for determining POZs for various different criteria according to some implementations. In some examples, the process 900 may be executed by the system 100 discussed above. For example, the process 900 may be executed by the data analytics platform 145, such as the service computing device(s) 108 executing the navigation information program 146 in some examples. Once a connected vehicle shares its current location and destination, the corresponding road segments may be calculated by the data analytics platform 145 for all the candidate routes to the destination location. The road segments may be divided into two categories: (1) road segments outside of any intersection functional area and (2) road segments inside of an intersection functional area. The POZ determining process 929 of the predictive data analytics layer may first identify the type of road segments and may then calculate the POZ for that road segment. The system may determine at least one POZ for each road segment of each candidate route.

At 902, the service computing device 108 may receive vehicle information including current location and destination from the vehicle ECU.

At 904, the service computing device 108 may determine candidate routes, waypoints, and functional areas of intersections.

At 906, the service computing device 108 may determine a current segment based on waypoints.

At 908, the service computing device 108 may determine whether the current segment is in the functional area of the intersection. If so, the process goes to 916. If not, the process goes to 910.

At 910, the service computing device 108 may determine V (design speed) and G (road grade) for the current segment.

At 912, the service computing device 108 may determine the stopping sight distance S based on the values for V and G determined at 910 (see EQ (5) below).

At 914, the service computing device 108 may determine POZ_{ST} for the current segment (e.g., segment is outside intersection functional area).

At 916, when the current segment is in the functional area of an intersection the service computing device 108 may determine a current zone of the functional area, e.g., the perception reaction distance zone, the maneuver distance zone, or the storage distance zone.

At 918, the service computing device 108 may determine whether the vehicle is within the perception reaction distance zone. If so, the process goes to 944. If not, the process goes to 920.

At 920, when the vehicle is within the functional area of the intersection but not within the perception reaction distance zone, the service computing device 108 may add the storage queue distance if available.

At 922, the service computing device 108 may determine whether the vehicle should change lanes, such as based on the intended destination. If so, the process goes to 924. If not, the process goes to 926.

At 924, if the vehicle should change lanes, the service computing device 108 may determine POZ_{M5} for the lane change (e.g., lane change inside functional area of intersection).

At 926, the service computing device 108 may determine whether the vehicle should make a turn. If so, the process goes to 936. If not, the process goes to 938.

At 928, if the vehicle will be making a turn at the intersection, the service computing device 108 may determine whether there is a traffic signal. If so, the process goes to 932. If not, the process goes to 930.

At 930, when there is not a traffic signal, the service computing device 108 may determine POZ_{M3} for the intersection (e.g., turn at an intersection with no traffic signal).

At 932, when there is a traffic signal, the service computing device 108 may determine the condition of the traffic signal.

At 934, based on the determined condition of the traffic signal, the service computing device 108 may determine POZ_{M4} for the intersection (e.g., turn at intersection with traffic signal).

At 936, if the vehicle will not be making a turn at the intersection, the service computing device 108 may determine whether there is a traffic signal. If so, the process goes to 940. If not, the process goes to 938.

At 938, when there is not a traffic signal, the service computing device 108 may determine POZ_{M1} for the intersection (e.g., no turn at intersection with no traffic signal).

At 940, when there is a traffic signal, the service computing device 108 may determine the condition of the traffic signal.

At 942, based on the determined condition of the traffic signal, the service computing device 108 may determine POZ_{M2} for the intersection (e.g., no turn at intersection with traffic signal).

At 944, when the vehicle is within the perception reaction distance zone, the service computing device 108 may determine whether the vehicle should change lanes. If so, the process goes to 948. If not, the process goes to 946.

At 946, when the vehicle was not going to change lanes, the service computing device 108 may determine POZ_{D2} for the current lane (e.g., no lane change).

At 948, when the vehicle is going to change lanes, the service computing device 108 may determine POZ_{D1} for the new lane (e.g., change lanes).

At 950, following determination of the POZ at one of 930, 934, 938, 942, 946, or 948, the service computing device 108 may perform at least one action based on at least the POZ, such as sending at least one signal, determining a POZ for a next segment of the candidate route, or the like.

Further, while examples of determining POZs have been provided herein, additional examples are provided in U.S. Pat. No. 12,123,729, which has been incorporated by reference herein above.

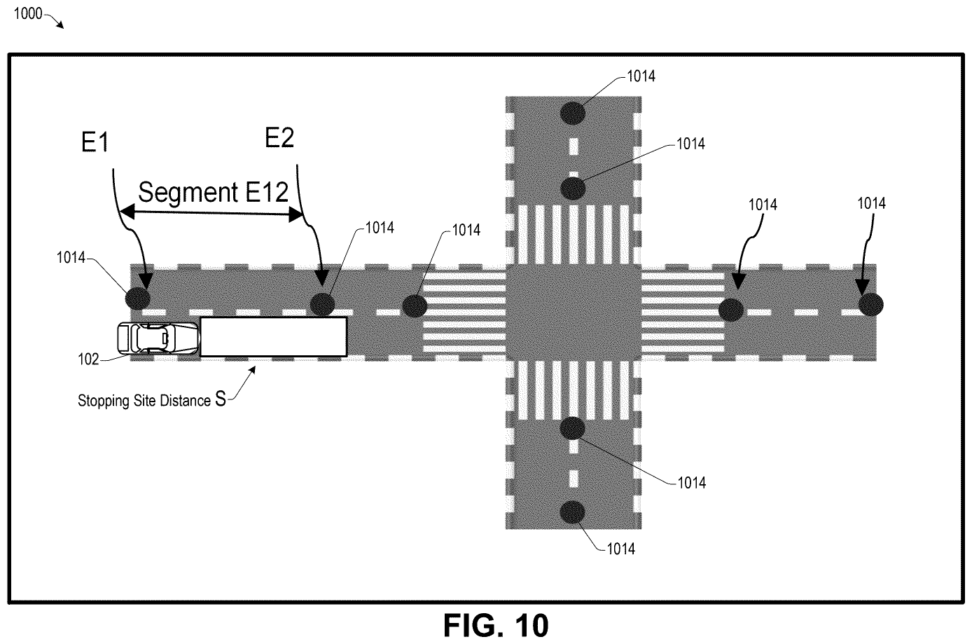

FIG. 10 illustrates an example 1000 of determining a POZ in which a current road segment falls outside of an intersection functional area according to some implementations. In this example, the vehicle 102 is located between a first waypoint 1014 designated as E1 and a second waypoint 1014 designated as E2. A plurality of other waypoints 1014 are also illustrated in this example. Accordingly a road segment between the waypoints E1 and E2 may be designated as segment E12 in this example. Further, suppose that the road segment E12 is located outside the intersection functional area discussed above with respect to FIGS. 8A and 8B. When a road segment is located outside of an intersection functional area, stopping sight distance S for that road segment may be calculated as shown in EQ (3):

$$S = ( 1.47 * V * t ) + 1.075 * ( {V}^{2} / a ) \qquad EQ ( 3 )$$

where,
S=Stopping sight distance
V=Road design speed (mph)
t=Perception reaction time
a=Deceleration rate

In addition, EQ (3) can be rewritten as shown in EQ (4) based on the typical values of t=2.5 sec and a=11.2 ft/sec²:

$$S = 3.675 * V + 0.096 * {V}^{2} \qquad EQ ( 4 )$$

Additionally, in the situation that the road is on a grade G, the stopping sight distance S can take the grade into consideration and may be calculated as shown in EQ (5):

$$S = 3.675 * V + {V}^{2} / [ 30 ( ( a / 32.2 ) \pm G / 100 ) ] \qquad EQ ( 5 )$$

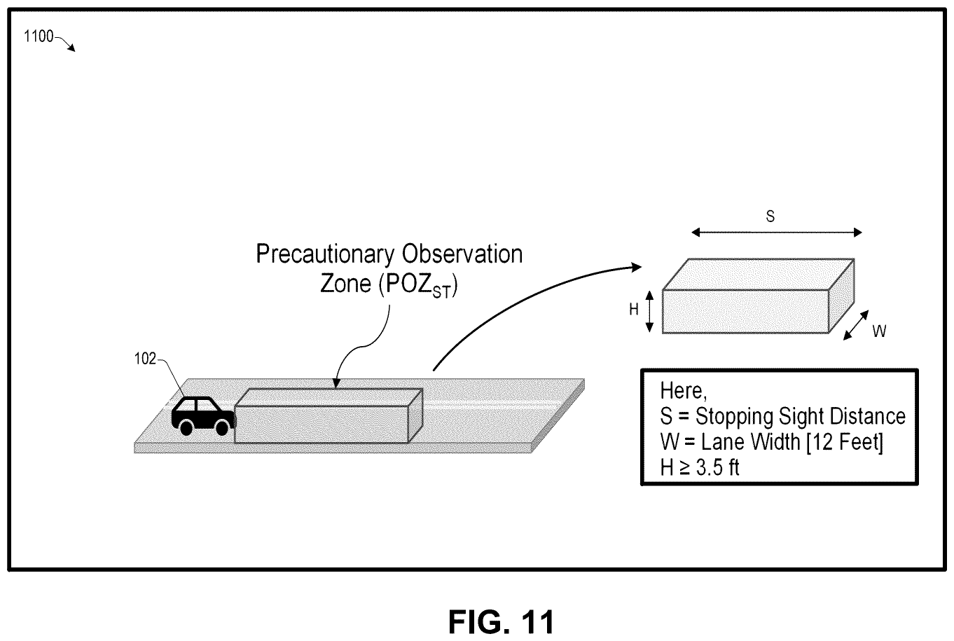

In some cases, the road design speed V and road grade G can be either stored in the data analytics platform 105 database(s) 154 for all routes or can be collected in real-time through third party services. Once the stopping sight distance S is calculated, the three-dimensional (3D) region of POZ_{ST} for the road segment outside the intersection functional area may be calculated as shown in FIG. 11 below, such as based on a lane width of 12 feet and a height of 3.5 ft.

FIG. 11 illustrates an example 1100 of determining a POZ according to some implementations. In this example, for road segments outside of intersection functional areas, the POZ is designated as POZ_{ST}, and may be determined as a volume in 3D space having a length corresponding to the stopping site distance S determined above with respect to FIG. 10; a width W corresponding to the width of the travel lane in which the vehicle 102 is traveling (or will travel), which in this example is a default value of 12 feet; and a height H, which in this example is a default height greater than or equal to 3.5 feet. In some examples, the height H may vary based on any of various factors, such as height of the vehicle, height of expected obstacles, signs, or signals, and so forth.

If a road segment falls inside of an intersection functional area, the next step is to identify its location based on the decision distance zone or ahead of the decision distance zone (maneuver and storage zone). In case the road segment is within the decision distance zone of the intersection functional area, the system may identify whether the vehicle needs to make a lane change or not based on the next segments of destination routes, three-dimensional POZ_{D1} and POZ_{D2} for the current segment may be calculated considering 12 ft width of lane and 3.5 ft height of driver eye distance from road.

In case the current segment is ahead of the decision distance zone, it is considered to be in the maneuver distance zone. Note that, based on the road type, location and/or traffic, etc. storage length or queue length might be added in some intersections. The storage length of any intersection can be calculated based on the traffic history data. Additionally, storage length can be predicted for any time on the day based on the infrastructure sensor or camera data. Thus, once the current segment is within the intersection functional area but not within the decision distance zone, the queue length may be added if available. Consequently, the POZ may be calculated considering a necessity of (further) lane change, making a turn or not, traffic signal intersection or sign-based intersection, etc. As explained above, e.g., with respect to FIG. 4, the POZ may be calculated in the predictive analytics layer for all road segments of all candidate routes. The POZ calculation can be done either in sequential or parallel computing modes. The POZs for the road segments may be stored in the map data database for future use. In this case, the POZ of any road segment immediately available in the map data database, and the system utilizes the stored POZs. The POZs determined for the respective road segments may be used to calculate the safety score for each road segment. To calculate the safety score, the 3D POZs of the road segments for every candidate route may be compared with vehicle sensor FOV. For each road segment, the percentage of 3D POZ covered (overlapped) by the vehicle sensor FOV is calculated. An average safety score percentage may be calculated for each candidate route by averaging the calculated percentage of overlap of the FOV for POZs of all road segments for that candidate route. This average percentage indicates the safety score of the entire route.

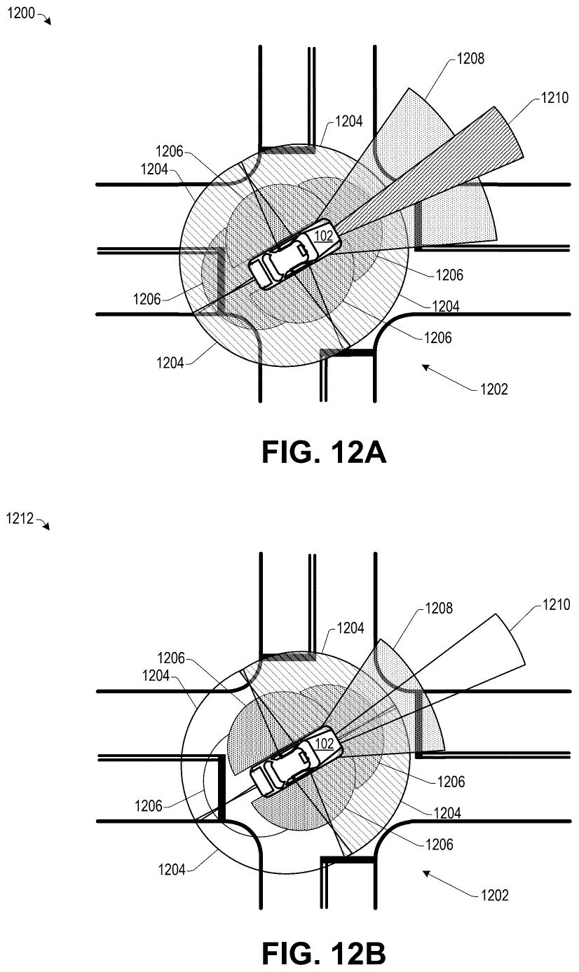

FIGS. 12A and 12B illustrate examples 1200 and 1212, respectively, of vehicle sensor operation at a POZ 1202 according to some implementations. Typical sensor configurations used for autonomous and semi-autonomous vehicles may include a combination of different types of sensors to realize 360 degrees monitoring around the vehicle 102 for levels 4 to 5 autonomous driving systems. An example sensor configuration is illustrated in FIG. 12A, which includes four mid-range radars 1204, four surround mono cameras 1206, a forward-facing stereo camera 1208, and a forward-facing long-range radar 1210. Further, while certain sensors and sensor configurations are illustrated and described with respect to FIG. 12A, numerous other sensors and sensor configurations will be apparent to those of skill in the art having the benefit of the disclosure herein.

In the example 1200 of FIG. 12A, after the system determines the POZ for each road segment, the system determines the necessary sensors and their fields of view (FOVs) that are required to monitor the POZ 1202 as the vehicle 102 traverses the corresponding road segment. As discussed above with respect to FIG. 4, in some examples, this determination may be performed by the prescriptive analytics modules 152 in the data management platform 145. Suppose in the example of FIG. 12A that all of the sensors 1204-1210 are fully active as the vehicle 102 traverses the POZ 1202, which in this example includes making a left-turn at an intersection. The sensor data may be preprocessed, compressed, filtered, fused, and processed by the recognition program 126 discussed above to identify the obstacles and road features around the vehicle. The recognition program 126 onboard the vehicle 102 may track the detected obstacles and features, as well as identify their location from the vehicle 102. For each sampling interval, vehicle trajectory and route planning as well as prediction algorithms to predict anomalies or so forth may be determined. Additionally, based on the recognition, localization, and planning outputs, the vehicle control program 124 may determine the acceleration, braking, steering, and other control signals for the vehicle systems of the vehicle 102.

Accordingly, in the example of FIG. 12A, sensors that are not necessary for safely traversing the POZ 1202 will continue to generate sensor data that may be stored and processed by the vehicle ECU. However, some of this generated sensor data is not particularly useful for safely traversing the POZ 1202. This can cause unnecessary consumption of memory and processing capacity of the vehicle ECU.

FIG. 12B illustrates an example 1212 in which the system optimizes the operation of the sensors 1204-1210 and their respective FOVs, as determined to be required for safely traversing the specific POZ 1202 of the road segment intersection at which the vehicle 102 is making a left turn. In this example, the system may determine that the mid-range radars 1204 and the mono camera 1206 that face the rear of the vehicle, as well as the forward-facing long-range radar 1210 are not necessary for safe traversal of the POZ 1202. Accordingly, these sensors may be deactivated, may have their sampling frequency significantly reduced, or the like. As another alternative, these sensors may continue to operate, but the generated sensor data may be ignored and/or deleted rather than being processed. Furthermore, in this example, the forward-facing stereo camera 1208 may have its range of detection reduced, but may otherwise continue to operate at its normal sampling rate. By using these techniques to reduce the amount of sensor data to be processed as the vehicle traverses the POZ 1202, the load on the SoC of the vehicle ECU is reduced, which in turn, reduces the power consumption and thereby reduces the heat load on the vehicle ECU.

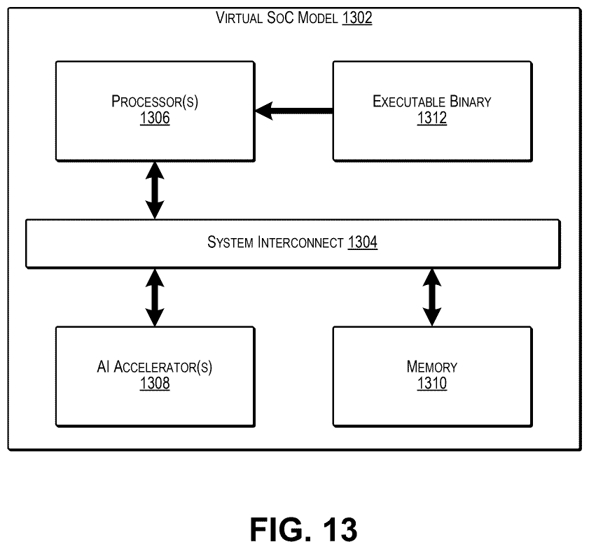

FIG. 13 illustrates an example configuration of a virtual model 1302 of a system-on-chip (SoC) according to some implementations. For instance, SoCs have become more powerful and complex to meet the real-time requirements of different applications that are executed for enabling automated driving. In some examples herein, the vehicle ECU may include one or more SoCs based on the vehicle specification. The virtual model 1302 of the SoC may be used to determine the usage of the SoC included in the vehicle ECU when traversing a road segment, and may provide information to one or more AI algorithms based on anticipated sensor data input information, such as based on predicted sensor usage and sensor FOV at a POZ of a road segment. Virtual modeling of the SoC(s) may basically correspond to virtual modeling of the vehicle ECU, and enables prediction of the power consumption of the vehicle ECU according to some examples herein.

There are various different technologies available for providing a virtual model of a SoC. A typical SoC includes one or more processors, such as one or more central processing units (CPUs), input and output devices, interfaces for graphics and memories, storage, USB connectivity, etc. In the case of SoCs used for vehicle ECUs, the SoC may also include a vision signal processing unit, artificial intelligence (AI) accelerator, etc.

The virtual SoC model 1302 of FIG. 13 illustrates a simplified SoC that includes a simulated system interconnect 1304, one or more simulated processors 1306 (e.g., simulating a CPU), one or more simulated AI accelerators 1308 for executing DNNs or other machine-trained models, and simulated memory 1310. The virtual model 1302 of the entire SoC can be made using different simulation frameworks or other commercially available simulation software. For instance the processor(s) 1306, system interconnect 1304, and memory 1310 can be modeled using a simulation platform used for simulating computer system architectures. The AI accelerator(s) 1308 can be modeled using a trace-based accelerator modeling framework or the like. To tie all the component functionalities together, an executable binary 1312 may be executed on the simulated processor(s) 1306 in the simulation framework, and the binary 1312 may handle the control and data flow of the executed application (e.g., the recognition program). Creation of the binary 1312 is discussed additionally below.

FIG. 14 is a flow diagram illustrating an example process 1400 for determining a tiling configuration to employ for a virtual AI model according to some implementations. In some examples, the process 1400 may be executed by the system 100 discussed above. For example, the process 1400 may be executed by the service computing device 108 executing the navigation information program 146. Alternatively, as mentioned above, in other examples, the process 1400 may be executed at least in part by at least one of a VEC 105 or the vehicle ECU 104.

To create a virtual model of an AI accelerator, several items need to be considered including dynamic memory allocation (DMA), the number of processing elements (PE) and corresponding multiplier accumulator (MAC), tightly coupled memory (TCM), and the like. Processing elements (PEs) and the tightly coupled memory (TCM) regions are used for storing the weights, inputs, and outputs for the current invocation. The TCM regions may also be referred to as “scratchpad memory”, and may interface with the rest of the system through a DMA engine.

At 1402, the computing device may determine an input tensor shape.

At 1404, the computing device may determine a weight tensor shape.

At 1406, the computing device may determine an optimal tiling strategy based at least on the input tensor shape and the weight. Since the TCM of the AI accelerator size is very small compared to the tensors for a deep neural network, the tensors may be broken up into smaller pieces called “tiles” to fit into the local memory of the AI accelerator. The process of breaking up the tensors is called tiling, and tiling strategies are determined in the data management platform 145 for the selected input image as discussed, e.g., with respect to FIG. 5 above.

At 1408, the computing device may determine any additional parameters, such as padding or stride.

At 1410, the computing device may determine any hardware parameters, such as number of processing elements and TCM region size.

At 1412, the computing device may determine the tiling strategy for the inputs, the weights, and the outputs. For deep neural networks with multiple layers, the tensors for each layer may be tiled independently. A tiling strategy defines the best set of dimensions along which to break up the input, weight, and output tensors.

At 1414, after the tiling strategy for inputs, weights and outputs has been determined, the computing device may determine the tile shapes that will be used for breaking up the original tensors.

At 1416, the computing device may determine a list of compatible tiling configurations.

At 1418, the computing device may select a tiling configuration that maximizes DMA utilization. For example, the tiling strategies that maximize the usage of DMA utilization may be finally selected at the optimal tiling configuration.

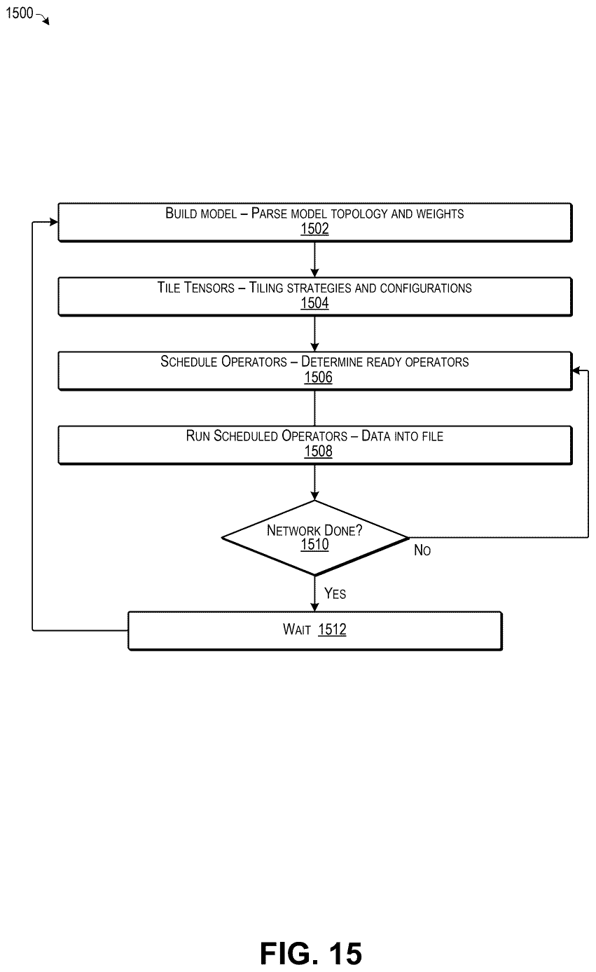

At 1420, the computing device may implement the selected tiling configuration as part of the virtual AI accelerator. FIG. 15 illustrates a tiling configuration that can be adopted for virtual modeling of a SoC.

FIG. 15 is a flow diagram illustrating an example process 1500 for scheduling operators according to some implementations. In some examples, the process 1500 may be executed by the system 100 discussed above. For example, the process 1500 may be executed by the service computing device 108 executing the navigation information program 146. Alternatively, as mentioned above, in other examples, the process 200 may be executed at least in part by at least one of a VEC 105 or the vehicle ECU 104.

At 1502, the computing device may build the model, which may include parsing model topology and weights.

At 1504, as discussed above, the computing device may determine tile tensors and tiling strategies and configurations.

At 1506, after at least one tiling strategy has been selected, the computing device may schedule operators and tiles. Scheduling of operators is useful for a deep neural network (DNN) as a DNN may include many operators like convolutions, pooling, matrix multiplications, etc. Two levels of scheduling can be considered for virtual models, scheduling of operators in a network and scheduling of tiles in a network.

At 1508, after the scheduling of operators and tiles are determined, the computing device runs the operators by creating an executable binary. The data flow control considering the selected input data and DNN(s) (for the selected road segment) are determined, e.g., as discussed above with respect to FIG. 5.

At 1510 the computing device may determine whether the network is finished. If so, the process goes to 1512. If not, the process goes back to 1506 to schedule another operator.

At 1512, when the network is done, the computing device may wait for an instruction for generating a next AI accelerator simulator.

The above description with respect to FIGS. 14 and 15 explains how design and computation of a virtual SoC model can be performed, such as in a cloud-based data management platform as shown in FIGS. 4 and 5. Several types of SoC might be included in a vehicle ECU, such as based on the input sensors and deep neural networks models. For example, a SoC can consist of multiple CPUs, multiple AI accelerators, and memory and each of these components are interconnected with high-speed communication interfaces/interconnects. The virtual model of the considered SoC which is built as explained above may be stored in the data management platform as discussed above with respect to FIG. 4. Additionally, as discussed above with respect to FIG. 5, the data management platform may determine an amount of MAC and memory usage of the virtual SoC for the selected networks. Furthermore, different neural networks may use different MAC and memory for a similar input image in a SoC. Moreover, virtual models may also calculate the time required to execute using a deep neural network as discussed above with respect to FIG. 5.

As explained above, utilizing the virtual SoC model, the SoC usage of the vehicle ECU may be simulated and predicted for every road segment of the selected or candidate route in the system described herein. The SoC included in the vehicle ECU may contain multiple CPUs and AI accelerators. Based on the SoC model and the TCM and memory usage, which are calculated using the virtual model, the system may calculate the approximate power usage of the SoC for every road segment. A lookup table and/or AI model can be used for this purpose. Additionally, the amount of heat (thermal load) generated by the SoC for every road segment may be estimated by the system herein. In the case of a connected vehicle, the system may receive the environmental temperature for each road segment. Thus, the system may also consider the outside temperature for each road segment. The system may then determine the amount of cooling required (liquid and/or air cooling) for the SoC of the vehicle ECU.

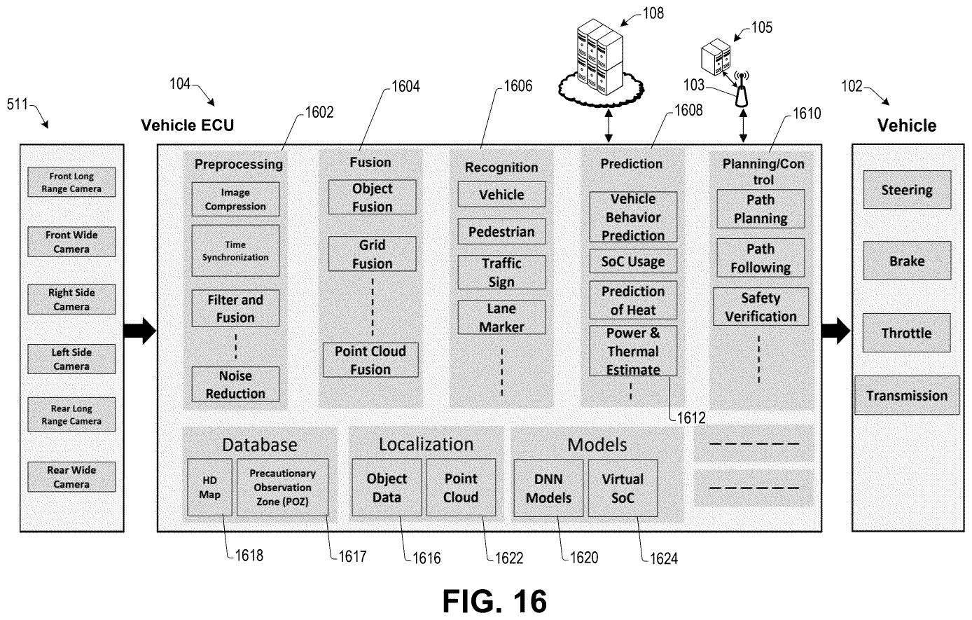

FIG. 16 illustrates an example schematic diagram of an autonomous driving control architecture 1600 according to some implementations. For example, automated driving software to control the vehicle autonomously (different levels of automation) may be executed by a vehicle ECU according to some examples herein. The automated driving controller includes different functions including data processing, fusion, recognition, prediction, risk map, planning, etc. Each of these functions also may include sub functions as shown. The amount of SoC usage as well as thermal and power management details can be estimated using the subfunctions of vehicle ECU, such as those shown. In a connected automated vehicle, the connected vehicle data management platform 145 discussed above can decide thermal management for every road segment in advance. This information is sent to the vehicle ECU where thermal management is done on each road segment, which may include consideration of the local weather conditions. The proposed system can also be used for vehicles that are not connected with a connected vehicle data management platform. In such a case, the vehicle ECU includes all models (e.g., DNN, Virtual SoC models, etc.) and software capable of performing POZ calculations in its local memory/database. Based on the computing requirements and available resources, roadside VEC and vehicle ECU could also share some of the functions (e.g., preprocessing, recognition, prediction, localization, etc.) or subfunctions required to determine a vehicle control signal or other instructions for controlling the vehicle 102.

In the example of FIG. 16, the vehicle ECU(s) 104 discussed above with respect to FIG. 1 may include a vehicle ECU 104 including a SoC that may perform a plurality of different functions, such as data preprocessing 1602, fusion 1604, recognition 1606, prediction 1608, planning/control 1610, and so forth. For example, the data preprocessing 1602 may include image compression, time synchronization, filtering and fusion, noise reduction, and so forth. The fusion 1604 may include object fusion, grid fusion, point cloud fusion, and the like. The recognition 1606 may include vehicle recognition, pedestrian recognition, traffic sign recognition, lane marker recognition, and so forth. The prediction 1608 may include vehicle behavior prediction, predicted SoC usage, predicted heat generated by a vehicle ECU, and estimated power and thermal loads 1612 on the SoC. Furthermore, the planning/control 1610 may include path planning, path following, and safety verification.

The vehicle ECU(s) 104 may receive images from a plurality of cameras such as a front long range camera, a front wide-angle camera, a right side camera, a left side camera, a rear long range camera, and a rear wide-angle camera, or the like. In addition, based at least in part on the estimated power and thermal loads 1612, the vehicle ECU 104 may control one or more cooling devices associated with the vehicle ECU, such as a fan or other air cooling device, and/or a liquid cooling device. The vehicle ECU 104 may send instructions (e.g. a control signal) to one or more components of the vehicle 102, such as steering, brakes, throttle, transmission, and the like, for controlling the vehicle 102.

In some examples, the vehicle ECU(s) 104 may control the vehicle 102 by executing the vehicle control program using the vehicle ECU(s) 104. In some cases, the roadside VEC 105 may also include an automated driving controller (e.g., may have the same capabilities as the vehicle ECU 104). If the VEC 105 has sufficient sensor coverage (e.g., infrastructure sensor data or other vehicle sensor data) to cover the entire POZ of a related road segment, as well as sufficient computing resources, the VEC 105 may utilize the automated driving control architecture, as shown in FIG. 16, to send vehicle control signals to the vehicle 102 for controlling the vehicle components for navigation of the vehicle 102 on the road segment.

Alternatively, in the case that the VEC 105 does not have sufficient sensor data to cover the entire POZ, but only the coverage for the region needed by the vehicle 102, the VEC may utilize the preprocessing modules 1602 of the automated control architecture and send the recognition results or recognition features to the vehicle ECU 104 having the SoC and included in the vehicle ECUs 104. The vehicle ECU onboard the vehicle 102 can utilize the recognition results and/or features for sensor fusion, and may identify the obstacles, road features, road anomalies, etc., that may ultimately be used for generating vehicle control signals. As another example, based on the computing requirements and available resources, the VEC 105 and the vehicle ECU 104 may share functions (fusion, recognition, risk map prediction, localization, etc.) or other subfunctions performed to calculate the vehicle control signals for controlling the vehicle 102.

In some examples, as discussed above, the POZs 1617 may be used to reduce/optimize the number of sensors being used by the vehicle based on the vehicle's location. For example, an automated vehicle 102 does not necessarily need to utilize all its sensors in every scenario. For example, an automated vehicle 102 traversing on a straight highway does not need to utilize its rear and side sensors all the time and so may lower the sampling rate or the like for those sensors in that scenario. On the other hand, at least side and some front sensors are necessary during a turn at an intersection, but a longer-range front sensor may not be necessary. Accordingly, implementations herein may use the POZs to estimate the usage of necessary sensors to predict the data that will be processed by the SoC at each POZ 1617 for predicting the power and thermal management of the vehicle ECU 104 including the SoC. Therefore, techniques herein include predicting the SoC usage in advance based on considering route information and virtual models 1624 of the SoC, which can ultimately enable power and thermal management of the vehicle ECU for realizing improved vehicle efficiency.

Moreover, the POZs 1617 can also be employed to optimize the number of prediction modules to execute and the amount of sensor data to process, such as for conserving processing power which in turn can improve the vehicle efficiency. For example, in the case where the vehicle is traveling between two intersections, it may not be necessary for the vehicle to execute a pedestrian prediction motion algorithm. Numerous additional advantages and variations will be apparent to those of skill in the art having the benefit of the disclosure herein.

Furthermore, in some examples, the POZs 1617 may be calculated in the prediction 1608 as part of the power and thermal estimate 1612. The vehicle ECU 104 may store or access databases that may include the calculated POZs 1617, as well as map data such as an HD map 1618. Furthermore, the vehicle ECU 104 may store localization data such as object data 1616 and point cloud data 1622. The vehicle ECU 104 may further store or access the models, such as DNN models 1620 or other machine-trained models, and the virtual SoC model 1624.

The example processes described herein are only examples of processes provided for discussion purposes. Numerous other variations will be apparent to those of skill in the art in light of the disclosure herein. Further, while the disclosure herein sets forth several examples of suitable frameworks, architectures and environments for executing the processes, the implementations herein are not limited to the particular examples shown and discussed. Furthermore, this disclosure provides various example implementations, as described and as illustrated in the drawings. However, this disclosure is not limited to the implementations described and illustrated herein, but can extend to other implementations, as would be known or as would become known to those skilled in the art.

Various instructions, processes, and techniques described herein may be considered in the general context of computer-executable instructions, such as computer programs and applications stored on computer-readable media, and executed by the processor(s) herein. Generally, the terms program and application may be used interchangeably, and may include instructions, routines, modules, objects, components, data structures, executable code, etc., for performing particular tasks or implementing particular data types. These programs, applications, and the like, may be executed as native code or may be downloaded and executed, such as in a virtual machine or other just-in-time compilation execution environment. Typically, the functionality of the programs and applications may be combined or distributed as desired in various implementations. An implementation of these programs, applications, and techniques may be stored on computer storage media or transmitted across some form of communication media.

Although the subject matter has been described in language specific to structural features and/or methodological acts, it is to be understood that the subject matter defined in the appended claims is not necessarily limited to the specific features or acts described. Rather, the specific features and acts are disclosed as example forms of implementing the claims.

What is claimed:

1. A system comprising:
one or more processors; and
one or more non-transitory computer-readable media including instructions executable by the one or more processors to configure the one or more processors to perform operations comprising:
determining a plurality of candidate routes between a source location for a vehicle and a destination location for the vehicle;
determining, for each candidate route, a predicted thermal load on a vehicle electronic control unit (ECU) of the vehicle for traversing the candidate route;
determining a cooling technique for the vehicle ECU based at least on the predicted thermal load for each candidate route;
selecting, for the vehicle, a first route of the plurality of candidate routes based in part on the first route predicted to have a lower energy expenditure for cooling the vehicle ECU than at least one other route of the plurality of candidate routes; and
sending, to the vehicle, information related to the first route and at least one selected cooling technique determined for the first route, wherein the vehicle utilizes the at least one selected cooling technique for cooling the vehicle ECU during traversal of the first route.

2. The system as recited in claim 1, the operations further comprising:
segmenting each candidate route of the plurality of candidate routes into multiple road segments;
determining a predicted thermal load on the vehicle ECU for each road segment; and
determining a cooling technique for the vehicle ECU for each road segment based at least on the predicted thermal load for each road segment, wherein sending the information related to the first route and the at least one selected cooling technique determined for the first route, includes sending information including a respective selected cooling technique to use for each road segment of the first route.

3. The system as recited in claim 2, wherein, based at least on receiving the information including the respective selected cooling technique to use for each road segment of the first route, the vehicle utilizes a first cooling technique for cooling the vehicle ECU during traversal of a first road segment of the first route, and the vehicle utilizes a second cooling technique for cooling the vehicle ECU during traversal of a second road segment of the first route, wherein the first cooling technique includes operating an air cooling device and the second cooling technique includes operating a liquid cooling device.

4. The system as recited in claim 1, wherein selecting the first route for the vehicle is further based in part on at least one of: predicted vehicle safety when traversing the first route; a predicted amount of travel time to traverse the first route; a predicted cost to traverse the first route; predicted vehicle efficiency when traversing the first route; or a predicted amount of the first route able to be traversed using automated driving.

5. The system as recited in claim 1, the operations further comprising:
segmenting each candidate route of the plurality of candidate routes into multiple road segments;
determining, for an individual road segment, an observation zone to be monitored by one or more sensors of the vehicle;
determining at least one machine-trained model for the observation zone;
determining a predicted power consumption of the vehicle ECU based at least on the observation zone, the one or more sensors, and the at least one machine-trained model; and
determining a cooling technique to use for the individual road segment based at least on the predicted power consumption.

6. The system as recited in claim 1, wherein determining the predicted thermal load on the vehicle ECU includes employing a virtual model of a system-on-chip for simulating processing of sensor data and execution of a machine-trained model at one or more locations on each candidate route for determining a predicted power consumption of the vehicle ECU if the vehicle were to traverse the candidate route.

7. The system as recited in claim 6, the operations further comprising:
generating a virtual model of at least an artificial intelligence accelerator to employ with the machine-trained model and the virtual model of the system-on-chip when simulating the processing of the sensor data.

8. A method comprising:
determining, by one or more processors, a plurality of candidate routes between a source location for a vehicle and a destination location for the vehicle;
determining, for each candidate route, a predicted thermal load on a vehicle electronic control unit (ECU) of the vehicle for traversing the candidate route;
determining a cooling technique for the vehicle ECU based at least on the predicted thermal load for each candidate route;
selecting, for the vehicle, a first route of the plurality of candidate routes based in part on the first route predicted to have a lower energy expenditure for cooling the vehicle ECU than at least one other route of the plurality of candidate routes; and
sending, to the vehicle, information related to the first route and at least one selected cooling technique determined for the first route, wherein the vehicle utilizes the at least one selected cooling technique for cooling the vehicle ECU during traversal of the first route.

9. The method as recited in claim 8, further comprising:
segmenting each candidate route of the plurality of candidate routes into multiple road segments;
determining a predicted thermal load on the vehicle ECU for each road segment; and
determining a cooling technique for the vehicle ECU for each road segment based at least on the predicted thermal load for each road segment, wherein sending the information related to the first route and the at least one selected cooling technique determined for the first route, includes sending information including a respective selected cooling technique to use for each road segment of the first route.

10. The method as recited in claim 9, wherein, based at least on receiving the information including the respective selected cooling technique to use for each road segment of the first route, the vehicle utilizes a first cooling technique for cooling the vehicle ECU during traversal of a first road segment of the first route, and the vehicle utilizes a second cooling technique for cooling the vehicle ECU during traversal of a second road segment of the first route, wherein the first cooling technique includes operating an air cooling device and the second cooling technique includes operating a liquid cooling device.

11. The method as recited in claim 8, wherein selecting the first route for the vehicle is further based in part on at least one of: predicted vehicle safety when traversing the first route; a predicted amount of travel time to traverse the first route; a predicted cost to traverse the first route; predicted vehicle efficiency when traversing the first route; or a predicted amount of the first route able to be traversed using automated driving.

12. The method as recited in claim 8, further comprising:
segmenting each candidate route of the plurality of candidate routes into multiple road segments;
determining, for an individual road segment, an observation zone to be monitored by one or more sensors of the vehicle;
determining at least one machine-trained model for the observation zone;
determining a predicted power consumption of the vehicle ECU based at least on the observation zone, the one or more sensors, and the at least one machine-trained model; and
determining a cooling technique to use for the individual road segment based at least on the predicted power consumption.

13. The method as recited in claim 8, wherein determining the predicted thermal load on the vehicle ECU includes employing a virtual model of a system-on-chip for simulating processing of sensor data and execution of a machine-trained model at one or more locations on each candidate route for determining a predicted power consumption of the vehicle ECU if the vehicle were to traverse the candidate route.

14. The method as recited in claim 13, further comprising:
generating a virtual model of at least an artificial intelligence accelerator to employ with a machine-trained model and the virtual model of the system-on-chip when simulating the processing of the sensor data.

15. One or more non-transitory computer-readable media storing instructions which, when executed by one or more processors, configure the one or more processors to perform operations comprising:
determining a plurality of candidate routes between a source location for a vehicle and a destination location for the vehicle;
determining, for each candidate route, a predicted thermal load on a vehicle electronic control unit (ECU) of the vehicle for traversing the candidate route;
determining a cooling technique for the vehicle ECU based at least on the predicted thermal load for each candidate route;
selecting, for the vehicle, a first route of the plurality of candidate routes based in part on the first route predicted to have a lower energy expenditure for cooling the vehicle ECU than at least one other route of the plurality of candidate routes; and
sending, to the vehicle, information related to the first route and at least one selected cooling technique determined for the first route, wherein the vehicle utilizes the at least one selected cooling technique for cooling the vehicle ECU during traversal of the first route.

16. The one or more non-transitory computer-readable media as recited in claim 15, the operations further comprising:
segmenting each candidate route of the plurality of candidate routes into multiple road segments;
determining a predicted thermal load on the vehicle ECU for each road segment; and
determining a cooling technique for the vehicle ECU for each road segment based at least on the predicted thermal load for each road segment, wherein sending the information related to the first route and the at least one selected cooling technique determined for the first route, includes sending information including a respective selected cooling technique to use for each road segment of the first route.

17. The one or more non-transitory computer-readable media as recited in claim 16, wherein, based at least on receiving the information including the respective selected cooling technique to use for each road segment of the first route, the vehicle utilizes a first cooling technique for cooling the vehicle ECU during traversal of a first road segment of the first route, and the vehicle utilizes a second cooling technique for cooling the vehicle ECU during traversal of a second road segment of the first route, wherein the first cooling technique includes operating an air cooling device and the second cooling technique includes operating a liquid cooling device.

18. The one or more non-transitory computer-readable media as recited in claim 17, wherein selecting the first route for the vehicle is further based in part on at least one of: predicted vehicle safety when traversing the first route; a predicted amount of travel time to traverse the first route; a predicted cost to traverse the first route; predicted vehicle efficiency when traversing the first route; or a predicted amount of the first route able to be traversed using automated driving.

19. The one or more non-transitory computer-readable media as recited in claim 15, the operations further comprising:
segmenting each candidate route of the plurality of candidate routes into multiple road segments;
determining, for an individual road segment, an observation zone to be monitored by one or more sensors of the vehicle;
determining at least one machine-trained model for the observation zone;
determining a predicted power consumption of the vehicle ECU based at least on the observation zone and the one or more sensors, and the at least one machine-trained model; and
determining a cooling technique to use for the individual road segment based at least on the predicted power consumption.

20. The one or more non-transitory computer-readable media as recited in claim 15, wherein determining the predicted thermal load on the vehicle ECU includes employing a virtual model of a system-on-chip for simulating processing of sensor data and execution of a machine-trained model at one or more locations on each candidate route for determining a predicted power consumption of the vehicle ECU if the vehicle were to traverse the candidate route.
